(19) United States
(12) Patent Application Publication
(10) Pub. No.: US 2025/0257486 A1
(43) Pub. Date: Aug. 14, 2025

(54) ELECTROCATALYST FOR EFFICIENT NITRITE REDUCTION

(71) Applicant: City University of Hong Kong, Hong Kong (HK)

(72) Inventors: Zhanxi FAN, Hong Kong (HK); Yunhao WANG, Hong Kong (HK); Yuecheng XIONG, Hong Kong (HK)

(21) Appl. No.: 18/764,392

(22) Filed: Jul. 5, 2024

Related U.S. Application Data
(60) Provisional application No. 63/551,538, filed on Feb. 9, 2024.

(51) Int. Cl. C25B 11/089; C25B 1/27; C25B 3/25; C25B 11/037

(52) U.S. Cl. CPC C25B 11/089; C25B 1/27; C25B 11/037; C30B 28/04; C30B 29/52; C30B 29/60

(57) ABSTRACT

The present invention reports the general one-pot synthesis of IrNi-based nanostructures with unconventional hexagonal close-packed (hcp) phase. Notably, the as-synthesized hcp IrNi nanostructures demonstrate excellent catalytic performance towards electrochemical nitrite reduction for ammonia synthesis. Ex/in-situ characterizations and theoretical calculations reveal that the Ir—Ni interactions within hcp IrNi-based nanostructures improve electron transfer to benefit both nitrite activation and active hydrogen generation, leading to a stronger reaction trend of NO₂RR by greatly reducing energy barriers of rate-determining step.

### CROSS-REFERENCE TO RELATED APPLICATIONS

The present application claims the priority from the U.S. provisional patent application Ser. No. 63/551,538 filed Feb. 9, 2024, and the disclosure of which is incorporated herein by reference in its entirety.

### FIELD OF THE INVENTION

The present invention generally relates to at least the fields of nanomaterial synthesis, electrocatalysis, ammonia synthesis, and so forth.

### BACKGROUND OF THE INVENTION

Human activities including over-fertilization and fossil fuel combustion have drastically perturbed the equilibrium of the nitrogen cycle, posing severe threats to the health of human and environment. In particular, as an essential intermediate in the global nitrogen cycle, nitrite (NO₂⁻) is classified as a Group 2A carcinogen by World Health Organization (WHO), which can cause critical diseases, such as blue baby syndrome, cellular degradation, and hypertension. Therefore, it is imperative to convert hazardous NO₂⁻ into harmless and useful products to harmonize the nitrogen cycle and sustain the global ecosystem.

Ammonia (NH₃) is not only a globally significant commodity for agriculture, pharmaceutical industry and chemical engineering, but also a long-term carbon-free energy carrier for the sustainable energy storage system owing to its high energy density (4.32 kW h L⁻¹) and large hydrogen storage capacity (17.6 wt. %). Ammonia is traditionally produced by the Haber-Bosch method, involving the energy-intensive reaction between nitrogen and hydrogen under high temperature and high pressure (i.e., 20-25 MPa, 300-500° C.). As an appealing alternative, NH₃ synthesis through electrochemical strategy is very popular because of its mild operation conditions and compatibility with renewable electricity resources. It only requires a low energy input and avoids fossil fuel consumption and greenhouse gas emission.

Electrocatalytic NO₂⁻ reduction reaction (NO₂RR) enables the simultaneous removal of NO₂⁻ contaminant and production of valuable NH₃. However, it should be mentioned that electrocatalytic NO₂RR to NH₃ is a complicated proton-coupled electron transfer process (i.e., NO₂⁻+7H⁺+6e⁻→NH₃+2H₂O) that involves the adsorption/desorption of multiple intermediates, which still suffers from low activity and poor selectivity.

So far, tremendous efforts have been devoted to modulating the size, composition, defect and dimension of catalysts to improve their performance towards NO₂RR, but the effect of crystal phase, as a key structural parameter, is rarely investigated. Therefore, it is of great significance to develop high-performance electrocatalysts for efficient nitrite reduction.

Recently, crystal phase engineering has been emerging as an effective approach to modulate the intrinsic physicochemical properties of metal nanomaterials, and thus improve their catalytic activities. To date, various monometallic nanomaterials with unconventional crystal phases, such as face-centered cubic (fcc)-2H-fcc heterophase gold, fcc ruthenium, 2H palladium and hexagonal close-packed (hcp) rhodium, have been obtained and demonstrated much superior catalytic activities over their common phase counterparts in different electrochemical reactions. Note that the catalytic performance of monometallic nanomaterials usually suffers from the limited types of adsorption sites on the surface, which makes it difficult to achieve the concurrent adsorption and stabilization of multiple intermediates in the multistep reactions like NO₂RR.

Noble metal nanomaterials have attained intensive research interests because of their unique physicochemical properties and promising potential in versatile applications, especially in catalysis. Recently, the development of crystal phase engineering of nanomaterials has revealed that noble metal-based alloys with unconventional phase could show superior catalytic performances to their common phase alloy counterparts owing to the distinct atomic arrangements and electronic structures.

Xu, Jie, et al.¹ provides the Ni@IrNi nanoparticles by the wet chemical reduction of Ir³⁺ and Ni²⁺ in the presence of oleylamine. Lv, Fan, et al.² provides the IrNi nanoflowers by the wet chemical reduction of IrCl₃ xH₂O and Ni(acac)₂ in oleylamine. However, all of them adopt the common fcc phase.

In this regard, the rational design and delicate construction of unconventional phase alloy nanomaterials composed of different metal elements could be a promising way to optimize their intrinsic properties and further boost their catalytic performance toward NO₂RR. Unfortunately, due to the vast differences in redox potentials, surface energies, and nucleation/growth behaviors of different metal components, it remains a big challenge to achieve the controlled synthesis of alloy nanomaterials with unconventional crystal phases.

### SUMMARY OF THE INVENTION

Currently, due to the kinetics mismatch of the multiple steps during NO₂RR, the existed catalysts still cannot meet the demand of the market requirement because of the drawbacks of limited NH₃ yield rate, low Faradaic efficiency and selectivity to NH₃, large overpotential, unsatisfied stability, etc. Therefore, it is of great significance to develop high-performance electrocatalysts for efficient nitrite reduction.

The present invention provides controlled synthesis of unconventional phase alloy nanostructures for highly selective electrocatalytic nitrite reduction to ammonia. In particular, the present invention provides an electrocatalyst for efficient nitrite reduction. The electrocatalyst includes one or more IrNi-based alloy nanostructures with an unconventional hexagonal close-packed phase, and the one or more IrNi-based alloy nanostructures have a Ni-rich core and an Ir-rich shell. A feeding atomic ratio of Ni to Ir is between 1:1 to 10:1.

In one embodiment, the feeding atomic ratio consists of 10-30 at % of Ir and 70-90 at % of Ni.

In one embodiment, the one or more IrNi-based alloy nanostructures include multi-rod-like nanobranches or nanoparticles.

In one embodiment, the one or more IrNi-based alloy nanostructures include IrNi nanobranches, IrRhNi nanobranches, or IrFeNi nanobranches.

In one embodiment, the feeding atomic ratio consists of 10-20 at % of Ir, 70-80 at % of Rh and 1-10 at % of Ni.

In another embodiment, the feeding atomic ratio consists of 10-20 at % of Ir, 70-80 at % of Fe and 10-15 at % of Ni.

In one embodiment, the one or more IrNi-based alloy nanostructures are capable of generating abundant *H for the hydrogenation of nitrogen-containing intermediates and thus reduce the overpotential for NH₃ production.

In one embodiment, each of the one or more IrNi-based alloy nanostructures has an average length of 125.6±4.4 nm and a middle-width of 16.6±0.3 nm.

In one embodiment, the electrocatalyst exhibits NH₃ Faradaic efficiency of at least 95% at 0 V compared to a reversible hydrogen electrode, a NH₃ yield rate of at least 30 mg h⁻¹ mg_{cat}⁻¹ at −0.1 V compared to the reversible hydrogen electrode, and an energy efficiency of at least 50% at 0 and 0.1 V compared to the reversible hydrogen electrode.

In another embodiment, the electrocatalyst exhibits the NH₃ Faradaic efficiency of 93.3% at 0 V compared to the reversible hydrogen electrode, even at a low nitrite concentration of 0.01 M.

In one embodiment, the electrocatalyst exhibits a partial current density of NH₃ (j_{NH3}) of at least 40 mA cm⁻² at −0.1 V compared to the reversible hydrogen electrode.

In one embodiment, the one or more IrNi-based alloy nanostructures possess catalytic durability over 20 consecutive electrolysis cycles.

In a second aspect, the present invention provides a one-pot method for synthesizing an unconventional phase IrNi-based alloy nanostructure, including co-reducing one or more metal precursors in a solution comprising at least one solvent, and performing ultrasonication to obtain a homogenous solution; adding a reductant and capping agent to the homogenous solution under vigorous stirring to obtain a growth solution; heating the growth solution from room temperature to 220° C. and maintained at this temperature for 10-15 hours; and cooling the growth solution to room temperature and collecting the unconventional phase IrNi-based alloy nanostructure.

In one embodiment, the one or more metal precursors include iridium salts, nickel salts, or a combination thereof.

In another embodiment, the one or more metal precursors further include a noble metal precursor to form the homogenous solution. The noble metal precursor includes rhodium salts, iron salts, or a combination thereof.

In one embodiment, the at least one solvent is selected from oleylamine (OAm), oleic acid (OA), or a combination thereof.

In one embodiment, the reductant and capping agent includes a formaldehyde solution.

In one embodiment, the concentration of the at least one solvent is in a range of 0.01-0.63 M.

In one embodiment, the concentration of the one or more metal precursors is in a range of 1-10 mg.

In one embodiment, the concentration of the reductant and capping agent is in a range of 0.1-0.8 M.

Compared with the other existing technology for the synthesis of electrocatalysts, the present invention provides a facile one-pot solvothermal method for the general synthesis of IrNi-based nanostructures with an unconventional hexagonal close-packed (hcp) phase, such as IrNi, IrRhNi and IrFeNi nanobranches (NBs). The method uses iridium (Ir), rhodium (Rh), iron (Fe) and nickel (Ni) salts as precursors, oleylamine and oleic acid as solvent, a formaldehyde solution as reductant and capping agent. The as-synthesized hcp IrNi NBs are composed of a Ni-rich core and an Ir-rich shell. This method has the following advantages, including easy operation, high yield of the products, good reproductivity and simple for scale-up production. The as-developed hcp IrNi NBs can be used in electrochemical nitrite reduction for ammonia synthesis. They can be used as highly efficient catalysts for electrocatalytic reactions such as hydrogen evolution reaction (HER), electrochemical nitrite reduction reaction (NO₂RR).

The yield of the products is very high and can be easily scaled up by increasing the volume of the solvent and amount of the reactants. In addition, the as-prepared hcp IrNi NBs demonstrate excellent faradaic efficiency and yield rate toward ammonia synthesis. In particular, the IrNi-based nanostructures with hcp phase demonstrate outstanding catalytic performance for NO₂RR, with superior Faradaic efficiency (FE) and yield rate of 98.2% and 34.6 mg h⁻¹ mg_{cat}⁻¹ (75.5 mg h⁻¹ mg_{Ir}⁻¹) toward NH₃ synthesis at 0 and −0.1 V (vs reversible hydrogen electrode (RHE)), respectively (FIG. 1).

Using IrNi-based nanobranches in the hcp phase (hcp IrNi NBs) as an example, the consecutive cycling electrolysis measurement suggests the excellent catalytic durability of hcp IrNi NBs. Electron paramagnetic resonance (EPR) and in-situ differential electrochemical mass spectrometry (DEMS) results indicate that hcp IrNi NBs can supply abundant active hydrogen for the hydrogenation step and significantly reduce the overpotential for NH₃ production. Density functional theory (DFT) calculations have revealed stronger Ir—Ni interactions within the hcp IrNi NBs than fcc counterpart. Due to the stronger Ir—Ni interaction in the hcp IrNi NBs than fcc counterpart, the electronic structures of both Ni and Ir have been optimized to supply more efficient electron transfer during NO₂RR. The hcp IrNi NBs generate active hydrogen more efficiently on the surface, which reduces the energy barriers and guarantees superior NO₂RR performance.

The advantages of this invention include: (1) This method provides a feasible strategy for the controllable preparation of nanomaterials with unconventional crystal phase. The reproducibility of the products will be high because of its simple synthesis procedure. The large-scale synthesis will also be easily achieved by scale-up the volume of the solvent and the amount of the metal precursors, demonstrating great potential for industrial production of hcp IrNi NBs in practical applications; (2) The synthetic strategy is a general method for the controlled synthesis of hcp phase IrNi-based nanostructures, including hcp IrNi, IrRhNi and IrFeNi nanostructures; (3) The as-prepared IrNi-based nanostructures can be used as catalysts in NO₂RR and exhibit high Faradaic efficiency and large yield rate toward ammonia synthesis, showing great potential in catalysis.

### BRIEF DESCRIPTION OF THE DRAWINGS

Embodiments of the invention are described in more details hereinafter with reference to the drawings, in which:

FIG. 1 shows an overview comparison between hcp IrNi and fcc IrNi;

FIG. 2A shows low-magnification TEM images of hcp IrNi NBs. FIG. 2B shows a TEM image of hcp IrNi NBs. FIG. 2C shows a STEM image of hcp IrNi NBs. FIG. 2D shows a HAADF-STEM image of a typical hcp IrNi NB. FIG. 2E shows atomic-resolution HAADF-STEM images of a typical hcp IrNi NB. FIG. 2F shows the zoom-in atomic-resolution HAADF-STEM image from the white dashed square-marked area in FIG. 2E;

FIG. 3 shows the characteristic stacking sequences of hcp phase and fcc phase along their close-packed directions. Characteristic stacking sequence of “AB” and “ABC” can be observed in hcp phase along [002]ₕ direction and fcc phase along [11]_{f} direction, respectively;

FIG. 4A shows a schematic illustration of hcp IrNi NBs. FIG. 4B shows the definition of the length and middle-width of the nanobranch. FIG. 4C shows size distributions of the length and middle-width of the hcp IrNi NBs, along with the Gaussian fitting curves;

FIG. 5 shows the SAED pattern of hcp IrNi NBs in FIG. 2A;

FIG. 6 depicts XRD characterization of hcp IrNi NBs. The characteristic peaks attributed to the hcp phase can be clearly identified in the XRD pattern, confirming the hcp phase of IrNi NBs (hcp IrNi NBs);

FIG. 7 shows the corresponding FFT pattern of the atomic-resolution HAADF-STEM image shown in FIG. 2E;

FIG. 8A shows composition analysis of hcp IrNi NBs. EDS spectrum of hcp IrNi NBs. Inset: a table demonstrating the weight ratio and atomic ratio between Ir and Ni. FIG. 8B shows HAADF-STEM image and the corresponding EDS line scanning of a typical hcp IrNi NB. FIG. 8C shows HAADF-STEM image and the corresponding EDS elemental mappings of hcp IrNi NBs;

FIG. 9A shows TEM images (left) and SAED patterns (right) of the products obtained by using different amounts (2 mg and 8 mg) of Ir(acac)₃. FIG. 9B shows TEM images (left) and SAED patterns (right) of the products obtained by using different amounts (2 mg and 8 mg) of Ni(acac)₂;

FIG. 10A shows a TEM image of the products obtained without adding Ni(acac)₂ while keeping the other reaction conditions the same. FIG. 10B shows a TEM image of the products obtained without adding Ir(acac)₃ while keeping the other reaction conditions the same;

FIG. 11A shows TEM images of the obtained products with the Ni:Ir atomic ratio of 1:2, 1:1, 5:1 and 10:1. FIG. 11B shows the XRD patterns of resultant products with different feeding atomic ratios of Ni:Ir;

FIG. 12 shows the EDS spectra of products with different feeding atomic ratios of Ni:Ir. Insets: tables demonstrating the weight and atomic ratios of Ir:Ni determined by EDS and ICP-OES;

FIG. 13A shows a TEM image of hcp IrRhNi NBs. FIG. 13B shows a HAADF-STEM image of hcp IrRhNi NBs. FIG. 13C shows atomic-resolution HAADF-STEM image of hcp IrRhNi NBs. FIG. 13D shows the corresponding FFT pattern generated from FIG. 13C;

FIG. 14 shows SAED pattern of hcp IrRhNi NBs;

FIG. 15 shows XRD characterization of hcp IrRhNi NBs. The characteristic peaks ascribed to the hcp phase can be clearly distinguished in the XRD pattern, confirming the hcp phase of IrRhNi NBs;

FIGS. 16A-16B show HRTEM images of hcp IrNi NBs. Inset: the corresponding FFT pattern of the selected area with the white dashed square in FIG. 16A. FIG. 16C shows the EDS spectrum of hcp IrNi NBs. Inset: a table demonstrating the weight ratio and atomic ratio between Ir and Ni;

FIG. 17A depicts a high-resolution XPS spectra of Ir 4f. FIG. 17B depicts a high-resolution XPS spectra of Rh 3d. FIG. 17C depicts a high-resolution XPS spectra of Ni 2p;

FIG. 18A shows composition analysis of hcp IrRhNi NBs. EDS spectrum of hcp IrRhNi NBs. Inset: a table demonstrating the weight ratio and atomic ratio between Ir, Rh and Ni. FIG. 18B shows HAADF-STEM image and the corresponding EDS line scanning of a typical hcp IrRhNi NB along the white dashed line. FIG. 18C shows the HAADF-STEM image and the corresponding EDS elemental mappings of individual hcp IrRhNi NBs;

FIG. 19A shows a TEM image of hcp IrFeNi NBs. FIG. 19B shows a HAADF-STEM image of hcp IrFeNi NBs. FIG. 19C shows a SAED pattern of hcp IrFeNi NBs, where the characteristic diffraction rings of hcp phase can be clearly identified. FIG. 19D depicts XRD characterization of hcp IrFeNi NBs. The characteristic peaks ascribed to the hcp phase can be clearly identified in the XRD pattern, confirming the hcp phase of IrFeNi NBs;

FIG. 20 shows an atomic-resolution HAADF-STEM image of hcp IrFeNi NBs;

FIG. 21 shows the corresponding FFT pattern generated from FIG. 20;

FIG. 22A shows high-resolution XPS spectra of Ir 4f. FIG. 22B shows high-resolution XPS spectra of Fe 2p. FIG. 22C shows high-resolution XPS spectra of Ni 2p;

FIG. 23A shows composition analysis of hcp IrFeNi NBs. EDS spectrum of hcp IrFeNi NBs. Inset: a table demonstrating the weight ratio and atomic ratio between Ir, Fe and Ni. FIG. 23B shows HAADF-STEM image and the corresponding EDS line scanning of a typical hcp IrFeNi NB along the dashed white line. FIG. 23C shows the HAADF-STEM image and the corresponding EDS elemental mappings of individual hcp IrFeNi NBs;

FIG. 24 shows high-resolution XPS spectra of Ir 4f of hcp IrNi NBs and fcc IrNi NPs;

FIG. 25 shows Ni 2p XPS spectra of hcp IrNi NBs and fcc IrNi NPs;

FIG. 26A shows normalized Ir L₃-edge XANES of hcp IrNi NBs, fcc IrNi NPs, Ir powder, and IrO₂. FIG. 26B shows Fourier transform k²-weighted EXAFS spectra of hcp IrNi NBs, fcc IrNi NPs, Ir powder, and IrO₂;

FIG. 27 depicts EXAFS fitting results of k²-weighted R space Ir L₃-edge of Ir powder, hcp IrNi NBs, and fcc IrNi NPs;

FIG. 28A shows normalized Ni K-edge XANES of hcp IrNi NBs, fcc IrNi NPs, Ni foil, and NiO. FIG. 28B shows Fourier transform k²-weighted EXAFS spectra of hcp IrNi NBs, fcc IrNi NPs, Ni foil, and NiO. FIG. 28C shows fitting results of k²-weighted R space Ni K-edge of Ni foil, hcp IrNi NBs, and fcc IrNi NPs;

FIG. 29A shows wavelet transforms of Ir L₃-edge EXAFS spectra of Ir powder, hcp IrNi NBs and fcc IrNi NPs. FIG. 29B shows wavelet transforms of Ni K-edge EXAFS spectra of Ni foil, hcp IrNi NBs and fcc IrNi NPs;

FIG. 30 depicts LSV curves of hcp IrNi NBs and fcc IrNi NPs in 1 M KOH with and without (w/o) 0.1 M KNO₂;

FIG. 31A depicts the current density of chronoamperometry measurements at different potentials with hcp IrNi NBs and fcc IrNi NPs. FIG. 31B depicts UV-vis absorption spectra with different concentrations of NH₄⁺; FIGS. 31C-31D depicts NH₃ FE and NH₃ yield rate of hcp IrNi NBs and fcc IrNi NPs at various potentials;

FIG. 32 depicts partial current densities of NH₃ (j_{NH3}) on hcp IrNi NBs and fcc IrNi NPs. The partial current densities of NH₃ at different potentials on hcp IrNi NBs and fcc IrNi NPs;

FIG. 33 depicts half-cell energy efficiency (EE) of hcp IrNi NBs and fcc IrNi NPs at various potentials;

FIG. 34A depicts NH₃ FE and yield rate of hcp IrNi NBs at 0 V (vs RHE) with different nitrite concentrations. FIG. 34B depicts LSV curves of hcp IrNi NBs with different KNO₂ concentrations. FIG. 34C depicts potential-dependent NH₃ FE of hcp IrNi NBs with different KNO₂ concentrations. FIG. 34D depicts NH₃ yield rate of hcp IrNi NBs with different KNO₂ concentrations. FIG. 34E depicts half-cell energy efficiency of hcp IrNi NBs with different KNO₂ concentrations;

FIG. 35A depicts LSV curves of hcp IrNi NBs with different KOH concentrations. FIG. 35B depicts potential-dependent NH₃ FE of hcp IrNi NBs with different KOH concentrations. FIG. 35C depicts NH₃ yield rate of hcp IrNi NBs with different KOH concentrations. FIG. 35D depicts half-cell energy efficiency of hcp IrNi NBs with different KOH concentrations;

FIG. 36A depicts the NH₃ FE and yield rate of hcp IrNi NBs in the neutral electrolyte composed of 0.5 M K₂SO₄ and 0.1 M KNO₂ at different potentials. FIG. 36B depicts the LSV curves of hcp IrNi NBs in the electrolyte composed of 0.5 M K₂SO₄ and 0.1 KNO₂. FIG. 36C depicts chronoamperometry plots of hcp IrNi NBs in the electrolyte composed of 0.5 M K₂SO₄ and 0.1 KNO₂;

FIG. 37 shows the chronoamperometry curves and the corresponding NH₃ yield rate of CP and hcp IrNi NBs in KOH and KOH+KNO₂;

FIG. 38 shows the ¹H NMR spectra of the electrolytes after electrolysis with and without KNO₂. The NMR spectra of the electrolytes after electrolysis using hcp IrNi NBs at 0 V (vs RHE) with and without KNO₂;

FIG. 39A shows the NH₃ FE and yield rate of hcp IrNi NBs at 0 V (vs RHE) by UV-vis and NMR methods. FIG. 39B shows ¹H NMR spectra of ¹⁴NH₄⁺ with different concentrations;

FIG. 40A depicts the chronoamperometry curves of hcp IrNi NBs during cycling stability test. The chronoamperometry curves of hcp IrNi NBs during the 20 consecutive electrolysis cycles at 0 V (vs RHE) in the electrolyte composed of 1 M KOH and 0.1 M KNO₂. FIG. 40B depicts the consecutive recycling electrolysis test of hcp IrNi NBs at 0 V (vs RHE) toward NO₂RR;

FIG. 41A shows a TEM image of hcp IrNi NBs after the 20 consecutive electrolysis cycles. FIG. 41B shows SAED pattern of FIG. 41A. FIG. 41C shows corresponding EDS spectrum. Inset: a table demonstrating the atomic ratio and weight ratio between Ir and Ni;

FIG. 42 shows Tafel slopes of hcp IrNi NBs and fcc IrNi NPs in NO₂RR;

FIG. 43 shows cyclic voltammetry curves of hcp IrNi NBs and fcc IrNi NPs within the potential range from 0 to 1.1 V (vs RHE) in 1 M KOH solution. The peak area of hcp IrNi NBs (0.109) is 20.7% larger than that of fcc IrNi NPs (0.090);

FIG. 44 shows DMPO-involved EPR spectra of hcp IrNi NBs and fcc IrNi NPs without and with NO₂⁻;

FIG. 45A shows electrochemical NO₂RR performance of hcp IrNi NBs with adding different concentrations of tert-butyl alcohol (TBA). LSV curves of hcp IrNi NBs with different TBA concentrations. FIG. 45B shows NH₃ yield rates of hcp IrNi NBs in the potential range from 0.3 to −0.1 V (vs RHE) without and with different TBA concentrations;

FIG. 46A depicts in-situ DEMS patterns of hcp IrNi NBs for NO₂RR. FIG. 46B depicts in-situ DEMS patterns of fcc IrNi NPs for NO₂RR. FIG. 46C shows the in-situ DEMS patterns for the detection of NH₂OH, NO, HNO, NH, NH₂ and H₂ on hcp IrNi NBs and fcc IrNi NPs during NO₂RR;

FIG. 47 depicts in-situ DEMS patterns for the detection of N* (f) and NH₃ (g) on hcp IrNi NBs and fcc IrNi NPs;

FIG. 48 depicts XRD patterns of obtained products by changing OAm to the other molecules;

FIG. 49 shows TEM images of the products obtained by replacing oleic acid with heptanol, benzyl alcohol and ethylene glycol;

FIG. 50 depicts XRD patterns of products obtained using different amounts of OA while keeping the overall volume of OAm and OA is 5 mL;

FIG. 51 shows TEM images of the obtained products by replacing the formaldehyde solution with benzaldehyde, benzaldehyde-water (the weight ratio of benzaldehyde is 37 wt. %), formic acid, formic acid-water (the weight ratio of formic acid is 37 wt. %), acetaldehyde and glyoxal;

FIG. 52 depicts XRD patterns of obtained products with different amounts of formaldehyde solution;

FIG. 53A shows the electronic distributions of bonding and anti-bonding orbitals near the Fermi level (E_{F}) of hcp IrNi NBs and fcc IrNi NPs. FIG. 53B shows the PDOSs of hcp IrNi NBs and fcc IrNi NPs;

FIG. 54 shows site-dependent PDOSs of Ir-5d orbitals in hcp IrNi NBs and fcc IrNi NPs;

FIG. 55 shows site-dependent PDOSs of Ni-3d orbitals in hcp IrNi NBs and fcc IrNi NPs;

FIG. 56 shows the PDOSs evolutions of key intermediates during NO₂RR on hcp IrNi NBs and fcc IrNi NPs;

FIG. 57 shows adsorption of key reactants on hcp IrNi NBs and fcc IrNi NPs;

FIG. 58 shows adsorption of all intermediates on hcp IrNi alloys including NO₂*, NO*, NHO*, NHOH*, N*, NH₂OH*, NH*, NH₂*, and NH₃*;

FIG. 59 depicts the reaction energies of NO₂RR;

FIG. 60 depicts the reaction energies of NO₂RR under an applied potential of −0.10 V;

FIG. 61 depicts the water dissociation energy comparison; and

FIG. 62 depicts the energy barrier of RDS with different active hydrogen (H*) coverage.

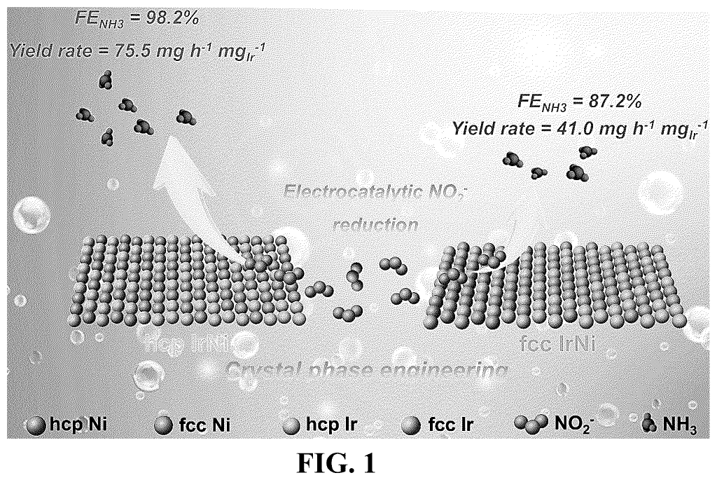

### DETAILED DESCRIPTION

In the following description, IrNi nanobranches with an unconventional hcp phase (hcp IrNi NBs), IrRhNi nanobranches with an unconventional hcp phase (hcp IrRhNi NBs), and IrFeNi nanobranches with an unconventional hcp phase (hcp IrFeNi NBs) are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

The precise synthesis of metal nanomaterials exhibiting unconventional phases holds immense importance in the development of high-performance catalysts for diverse applications. Despite the considerable challenges posed by the distinct redox potentials, surface energies, and nucleation/growth behaviors of various metal components, achieving controlled synthesis of alloy nanomaterials with unconventional crystal phases remains an arduous task. For instance, the ability to manipulate the atomic arrangements of metal nanomaterials, particularly alloy nanostructures involving metals with disparate redox potentials, continues to present a formidable challenge.

Accordingly, the present invention provides a general one-pot solvothermal method for the controlled synthesis of IrNi-based nanostructures with unconventional hcp phase. The obtained IrNi-based nanostructures (e.g., hcp IrNi, hcp IrRhNi and hcp IrFeNi NBs) possess a unique core-shell alloy structure containing a Ni-rich core and an Ir-rich shell. The as-developed hcp IrNi-based nanostructures can be used in electrochemical nitrite reduction for ammonia synthesis.

A working electrode is made as follows: the catalyst dispersed in ethanol were further washed by the mixture of ethanol and hexane (v/v=1/1) to remove the surfactants on their surface. Then, 0.8 mg of the catalysts were re-dispersed into 184 μL of isopropanol, followed by adding 16 μL of Nafion solution. Subsequently, it was ultrasonicated for about 1 h to enable the well dispersion of catalyst inks. After that, the resultant catalyst inks were dropped onto the carbon paper with an area of 1 cm² (1 cm×1 cm). After that, the obtained working electrodes were dried in the vacuum oven at room temperature for about 2 h. Then, the electrode was used for electrochemical nitrite reduction. The hcp IrNi-based nanostructures demonstrate much superior catalytic performance in NO₂RR compared to the fcc IrNi-based nanostructures. Significantly, hcp IrNi-based nanostructures exhibit an excellent NH₃ FE of 98.2% and large EE of 50.1% at 0 and 0.1 V (vs RHE), respectively. Meanwhile, the hcp IrNi-based nanostructures can also display an outstanding NH₃ yield rate of 34.6 mg h⁻¹ mg_{cat}⁻¹ (75.5 mg h⁻¹ mg_{Ir}⁻¹) at −0.1 V (vs RHE). Moreover, the hcp IrNi-based nanostructures also possess superior catalytic durability during the 20 consecutive electrolysis cycles.

In one embodiment, an excellent NH₃ FE of 93.3% can still be achieved at 0 V (vs RHE), even at a low nitrite concentration of 0.01 M.

In one embodiment, the hcp IrNi-based nanostructures can show an excellent FE of 98.6% and a superior yield rate of 18.7 mg h⁻¹ mg_{cat}⁻¹ toward NH₃ synthesis even in the neutral condition.

In the neutral-buffered solution composed of 0.5 M PBS (phosphate-buffered solution) and 0.1 KNO₂, the hcp IrNi-based nanostructures deliver excellent NH₃ FE of 96.3% and yield rate of 21.8 mg h⁻¹ mg_{cat}⁻¹ at −0.1 and −0.5 V (vs RHE), respectively. Additionally, the pH of the solution shows only a slight change after electrolysis compared to its initial state.

In one embodiment, the hcp IrNi-based nanostructures are capable of generating abundant *H for the hydrogenation of nitrogen-containing intermediates and thus reduce the overpotential for NH₃ production.

In one embodiment, the Ir—Ni interactions not only optimize the electronic structures of the catalyst but also accelerate the electron transfer efficiency on the hcp IrNi-based nanostructures. The superior NO₂RR performances are ascribed to the strong Ir—Ni interactions, which largely facilitate the stabilization of key intermediates and the generation of active hydrogen to reduce the reaction barriers.

In another aspect, this invention offers a facile and simple one-pot solvothermal method for the synthesis of IrNi-based nanostructures with unconventional crystal phase, which offers a feasible strategy for the rational design of advanced NO₂RR electrocatalysts towards a sustainable nitrogen cycle.

In another aspect, this method can also be used for the synthesis of ternary alloy structures with unconventional hcp phase.

### EXAMPLE

### Example 1—Materials and Methods

### Chemicals and Reagents

All the starting chemicals including solvents, metal precursors, reductants and capping agents are available from commercial sources. All the chemicals and reagents were used as received without any further treatment.

Iridium(III) acetylacetonate (Ir(acac)₃, 99%) and sodium nitroprusside (C₅H₄FeN₆Na₂O₃) were purchased from Alfa Aesar. Rhodium(III) acetylacetonate (Rh(acac)₃, 99%), Iron(III) acetylacetonate (Fe(acac)₃, 95%) and oleic acid (OA, 99%) were purchased from Sigma-Aldrich. Solution of sodium hypochlorite (NaClO, 0.1 M) was bought from Macklin. Nickel(II) acetylacetonate (Ni(acac)₂, 95%), oleylamine (OAm, 80-90%), formaldehyde (HCHO, 37 wt. % in H₂O), isopropyl alcohol (IPA, AR, ≥99.5%), tert-butyl alcohol (TBA, AR, ≥99%), potassium hydroxide (KOH, AR, 99%), potassium nitrite (KNO₂, AR, 99%), ammonium chloride (ACS, 99.5%), salicylic acid (AR, 99.5%), trisodium citrate dihydrate (98%), sodium hydroxide (NaOH, AR, 96%), maleic acid (AR, ≥99.0% (HPLC)), 5,5-dimethyl-1-pyrroline-N-oxide (DMPO, 97%) and deuterium oxide (D₂O, AR, 99%) were supplied by Shanghai Aladdin Biochemical Technology Co., Ltd. Ethanol (absolute, ≥99.9%) and hexane (99%) were obtained from Anaqua Global International Inc. Limited. All the chemicals and reagents were used as received without further purification. Deionized (DI) water used in the experiments was obtained from the Milli-Q Plus System with a resistance of 18.2 MΩ·cm.

The TEM and high-resolution TEM (HRTEM) images were taken on a JEOL-2100F transmission electron microscope operated at 200 kV. The spherical aberration-corrected high-angle annular dark-field scanning TEM (HAADF-STEM) images were obtained on a high-resolution aberration-corrected TEM (JEOL JEM-ARM200F). Scanning transmission microscope (SEM) measurements were conducted on QUANTA 250. Powder X-ray diffraction (XRD) patterns were recorded on a Rigaku SmartLab X-ray diffractometer with Cu Kα X-ray source (λ=1.5406 Å). X-ray photoelectron spectroscopy (XPS) test was performed on Thermo Scientific Nexsa spectrophotometer with Al-Kα radiation system. The calibration of the data was performed by using the C is peak at 284.8 eV. X-ray absorption spectroscopy (XAS) measurements were conducted on the beamline 1W1B Beijing Synchrotron Radiation Facility with the transmission mode. A double-crystal Si (111) monochromator was applied to monochromatize the radiation. Demeter 0.9.25 software package was used to subtract the background and normalize the XAS data. The edge energy of the X-ray absorption near edge structure (XANES) spectra were determined from the maximum value in the first derivative of the leading edge of the XANES spectrum. The coordination parameters were obtained by fitting the R-space Fourier transformed data using the least square in Artemis. Electron paramagnetic resonance (EPR) spectra were recorded on a Bruker EMXnano spectrometer using 5,5-dimethyl-1-pyrroline-N-oxide (DMPO) as the active hydrogen (H*) trapping agent. In-situ differential electrochemical mass spectrometry (DEMS) test was performed on the Linglu DEMS analysis system from Shanghai Linglu Instrument Co., Ltd.

### Methods

### NO₂RR Performance Test

The electrochemical NO₂RR performance test was performed in a H-type cell separated by a proton exchange membrane (Nafion 117). The catalyst-modified carbon paper, Pt plate, and Ag/AgCl (filled with saturated KCl) were used as the working electrode, counter electrode, and reference electrode, respectively. All the potentials were converted to the reversible hydrogen electrode (RHE) scale by the equation:

$$E ( vs . R H E ) = E ( vs A g / A g C l ) + 0.197 V + 0.059 \times pH \qquad ( 1 )$$

The solution containing 1 M KOH and 0.1 M KNO₂ was used as the electrolyte, which was purged with high purity argon (Ar) for at least 30 mins before the test. Then, 30 mL of electrolyte were added into both the anode and cathode compartments of the H-type cell. The linear sweep voltammetry (LSV) curves were acquired at a scan rate of 5 mV s⁻¹ with the potential range from 0.4 to −0.2 V (vs RHE). The chronoamperometry test was conducted for 1 h at each potential under a stirring rate of 600 rpm.

Electrochemical in-Situ DEMS Test

The in-situ DEMS test was performed with a homemade electrochemical cell. Pt wire, Ag/AgCl (filled with saturated KCl) and the catalyst-modified carbon paper were used as the counter electrode, reference electrode and working electrode, respectively. The electrolyte composed of 1 M KOH and 0.1 M KNO₂ was purged with high purity Ar for at least 30 mins before the measurement. The mass signals were recorded during the LSV scanning from 0.4 to −0.2 V (vs RHE). After the LSV test was finished, the next cycle of LSV test and mass signal collection started again when the mass signal intensity returned to the baseline.

### Determination of Ammonia by UV-Vis

The concentration of NH₃ was spectrophotometrically determined by using the reported indophenol blue method. Firstly, 2 mL of pre-diluted electrolyte were taken out and mixed with 2 mL of 1 M NaOH solution containing 5 wt. % of salicylic acid and 5 wt. % of trisodium citrate dihydrate. Then, the above solution was mixed with 1 mL of 0.05 M NaClO solution and 0.2 mL of aqueous solution of 1 wt. % sodium nitroprusside. After the above mixture was kept in the dark for 2 hours, the absorption spectrum was acquired using a UV-vis spectrophotometer (Shimadzu-UV1700) at the wavelength of 654 nm. The calibration curve of ammonia concentration and absorbance was prepared by using a series of standard NH₄Cl solutions.

### Determination of Ammonia by NMR

After conducting electrolysis for 1 hour, the electrolyte was collected and mixed with a certain amount of maleic acid, resulting in the concentration of 0.4 mg mL⁻¹ for maleic acid. After that, 0.45 mL of above solution was mixed with 50 μL of deuterium oxide (D₂O) for the ¹H-NMR (300 MHz) test. A series of ¹⁴N-¹⁴NH₄⁺ solutions with different ¹⁴NH₄⁺ concentrations were prepared using ¹⁴NH₄Cl. The calibration curve was obtained by correlating the relationship between ¹⁴NH₄⁺ concentration and the peak area ratio of H⁻¹⁴NH₄⁺ and H-maleic acid.

### Calculation of the Faradaic Efficiency (FE), Yield Rate (R) and Half-Cell Energy Efficiency (EE)

In the present invention, the FE of NH₃, N₂H₄ and H₂ were calculated as follows:

$${FE}_{{NH}_{3}} = ( 6 \times F \times {C}_{{NH}_{3}} \times V ) / ( {M}_{{NH}_{3}} \times Q ) \times 100 \% \qquad ( 2 )$$

$${FE}_{{N}_{2} {H}_{4}} = ( 7 \times F \times {C}_{{N}_{2} {H}_{4}} \times V ) / ( {M}_{{N}_{2} {H}_{4}} \times Q ) \times 100 \% \qquad ( 3 )$$

$${FE}_{{H}_{2}} = ( 2 \times F \times {C}_{{H}_{2}} \times V ) / ( {M}_{{H}_{2}} \times Q ) \times 100 \% \qquad ( 4 )$$

The yield rate of NH₃ was calculated according to the following equation:

$${R}_{{NH}_{3}} = ( {C}_{{NH}_{3}} \times V ) / ( {m}_{cat} \times t ) \qquad ( 5 )$$

where F was the Faraday constant (96485 C mol⁻¹); C_{NH3} represented the concentration of NH₃ (mg/L); V was the volume of the electrolyte (L); M_{NH3} denoted the molar mass of NH₃ (mg/mol); Q was the total amount of charge (C); meat was the total amount of the catalyst (mg); and t was the potentiostatic test time (h).

The half-cell energy efficiency was defined as the ratio of chemical energy to applied electrical power, which was calculated by the following equation:

$${EE}_{NH 3} = \frac{( {E}_{OER}^{0} - {E}_{NH 3}^{0} ) \times {FE}_{NH 3}}{{E}_{OER} - {E}_{NH 3}} \qquad ( 6 )$$

where E_{OER}⁰ represented the equilibrium potential of water oxidation (1.23 V vs RHE); E_{NH3}⁰ (0.65 V vs RHE under alkaline condition) was the equilibrium potential of nitrite electroreduction to NH₃; FE_{NH3} was the Faradaic efficiency for NH₃; E_{OER} was the applied potential (here assuming the overpotential for water oxidation is zero, i.e. E_{OER} was 1.23 V vs RHE); E_{NH3} was the applied potential for NH₃ production after 85% iR compensation.

### Theoretical Calculations Setup

To investigate the superior electroactivity of the unusual hcp phase of IrNi-based nanostructures, density functional theory (DFT) calculations were performed based on the embedded CASTEP packages. To supply an accurate description of the exchange-correlation interactions in the electrocatalysts, the present invention selected the generalized gradient approximation (GGA) and Perdew-Burke-Ernzerhof (PBE) functionals. Depending on the selection of ultrasoft pseudopotentials and ultrafine quality, the plane-wave cutoff energy had been determined as 380 eV by default. For the energy minimization process, the Broyden-Fletcher-Goldfarb-Shannon algorithm and coarse k-point had been applied for all the models. The solvation effect was considered based on the minimal-parameter implicit solvation model, which was based on the iso-density scheme. Based on this scheme, the DFT described the solute, while a dielectric continuum with a spatially varying permittivity represented the solvent. The permittivity changed smoothly, approaching the bulk value far from the solute, and 1 in the vicinity of the solute.

The hcp IrNi-based nanostructures were constructed based on (001) surfaces of the hcp Ni structures, which included six layers as the core part and two layers as the shell part. The overall Ni/Ir ratio was 3.8/1, which was close to the experimental result, where the core part was Ni-rich and the shell part was Ir-rich. The fcc IrNi was cleaved from the (111) surface of the conventional fcc Ni structure, which had five-layer thicknesses and the Ni/Ir ratio of 4/1. For all the catalyst surfaces, 20 Å vacuum space was also introduced to supply sufficient space for the geometry optimization. During the geometry optimization, the following criteria was applied to guarantee the convergence, which required that the Hellmann-Feynman forces and total energy difference should be smaller than 0.001 eV/Å and 5×10⁻⁵ eV/atom, respectively.

### Example 2

### Synthesis of the Unconventional Hcp IrNi NBs

4 mg of Ir(acac)₃ and 4 mg of Ni(acac)₂ were co-reduced in the 5 mL mixture of oleylamine (OAm) and oleic acid (OA) (v/v=7.3/1), followed by ultrasonication for about 2 hours to obtain a homogenous solution. Then, 100 μL of HCHO solution was added into the aforementioned solution dropwise under vigorous stirring. After that, the mixture was further stirred for another 20 mins at room temperature. Subsequently, the obtained growth solution was transferred to a Teflon-lined autoclave (25 mL capacity), which was heated from room temperature to 220° C. and maintained at this temperature for 14 hours. After the reactor was cooled down to room temperature naturally, the final products were collected and washed by centrifugation with 3 mL of a mixture of ethanol and hexane (v/v=1/2) for three times. Finally, the products were re-dispersed into 3 mL of ethanol for future use.

### Synthesis of Hcp IrRhNi NBs and Hcp IrFeNi NBs

4 mg of Ir(acac)₃, 0.5 mg of Rh(acac)₃ and 4 mg of Ni(acac)₂ were firstly added into 5 mL of the OAm/OA mixture (v/v=7.3/1), followed by ultrasonication for about 3 h to obtain the homogenous solution. Then, 100 μL of HCHO solution were added into the aforementioned solution dropwise under vigorous stirring. After that, the mixture was further stirred for another 20-30 mins at room temperature until the solution became transparent. Subsequently, the obtained growth solution was transferred to a Teflon-lined autoclave (25 mL capacity), which was heated from room temperature to 220° C. and maintained at this temperature for 14 h. After the reactor was cooled down to room temperature naturally, the final products were collected and washed by centrifugation with 3 mL of a mixture of ethanol and hexane (v/v=1/2) for three times. Finally, the products were re-dispersed into 3 mL of ethanol for future use.

The synthesis of IrFeNi NBs is similar to that of IrRhNi NBs except that Rh(acac)₃ was replaced with Fe(acac)₃. The obtained products were also re-dispersed into 3 mL of ethanol for future use.

### Synthesis of Fcc IrNi Nanoparticles (NPs)

In a typical synthesis of fcc IrNi NPs, 8 mg of Ir(acac)₃ and 8 mg of Ni(acac)₂ were added into 5 mL of OAm. After ultrasonication for about 1 h, the resultant solution was transferred to a Teflon-lined autoclave (25 mL capacity), which was heated from room temperature to 220° C. and maintained at this temperature for 12 h. After the reactor was cooled down to room temperature naturally, the final products were collected by centrifugation and washed three times with 3 mL of the mixture of hexane and ethanol (v/v=1/1). Finally, the obtained products were re-dispersed into 2 mL of ethanol for further use.

### Example 3

### Structure Characterization of the Unconventional Hcp IrNi-Based NBs

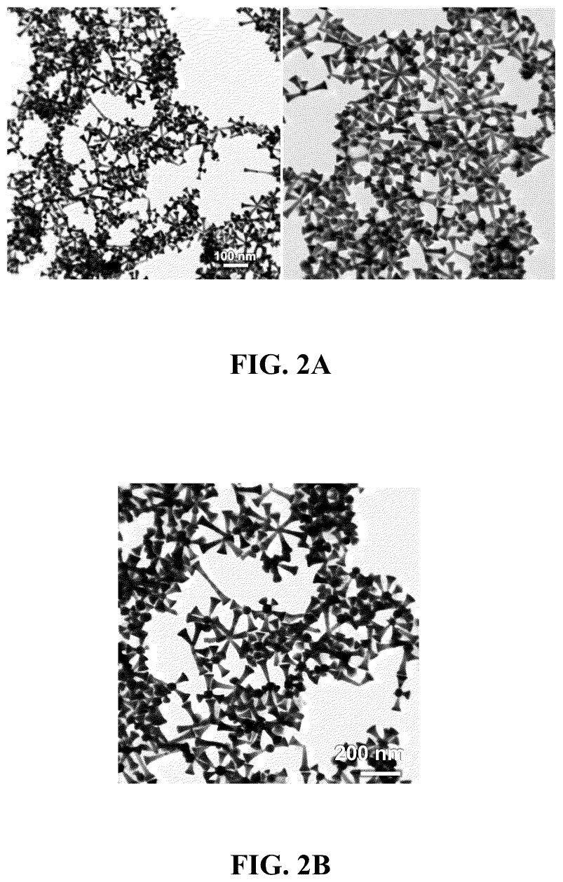

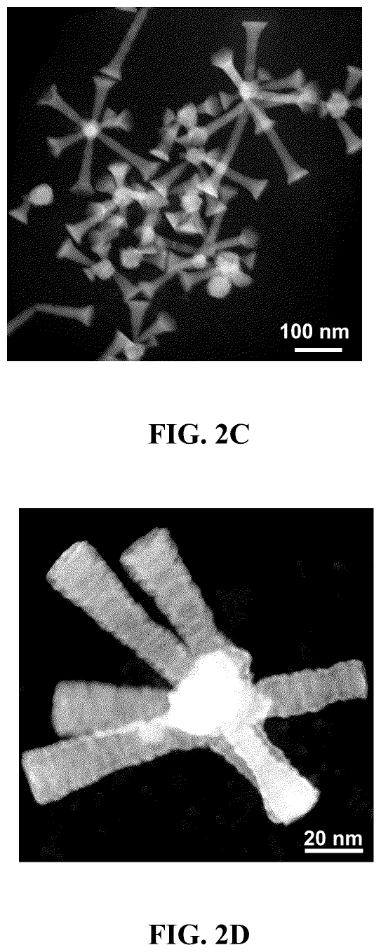

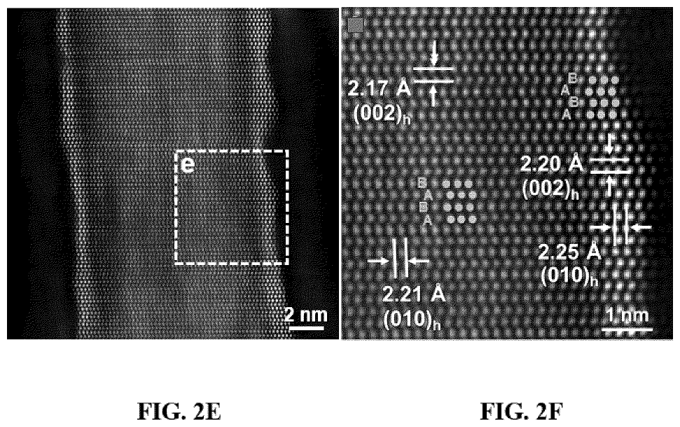

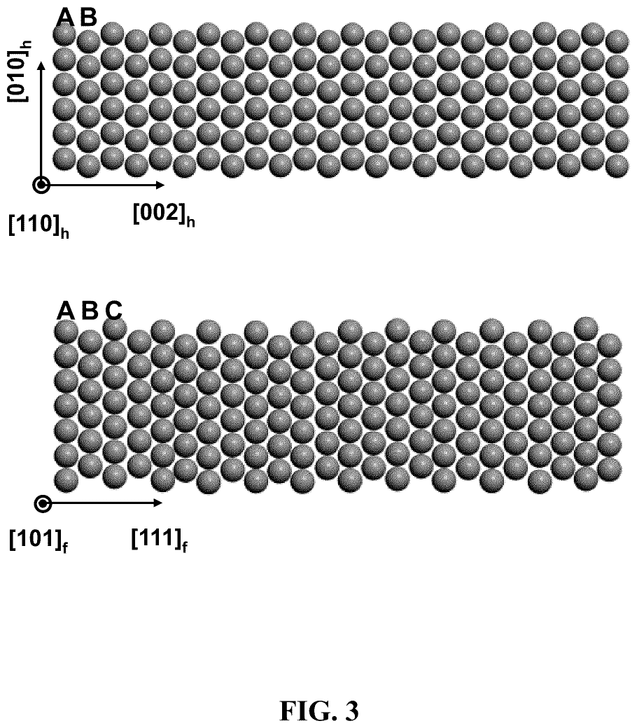

The low-magnification transmission electron microscopy (TEM) images showed the high purity of the as-prepared hcp IrNi NBs (FIG. 2A). The crystal structures were characterized by the atomic resolution HAADF-STEM. TEM and high-angle annular dark-field scanning TEM (HAADF-STEM) images demonstrated that the obtained products were composed of multi-rod-like nanobranches (FIGS. 2B-2D). As shown in the spherical aberration-corrected HAADF-STEM images, there was a strong contrast between the inside and outside areas of nanobranches, indicating the unique core-shell structure of hcp IrNi NBs (FIGS. 2E-2F). The zoom-in HAADF-STEM image in FIG. 2E clearly identified the characteristic stacking sequence of “AB” along the close-packed [001]h direction of hcp phase (FIG. 3). The interplanar spacings of 2.17 (2.20) and 2.21 (2.25) Å are assigned to (002)ₕ and (010)ₕ facets of hcp IrNi NBs at the core (shell) sites, respectively.

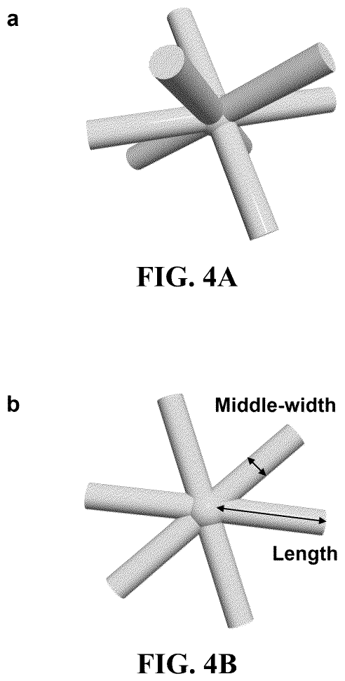

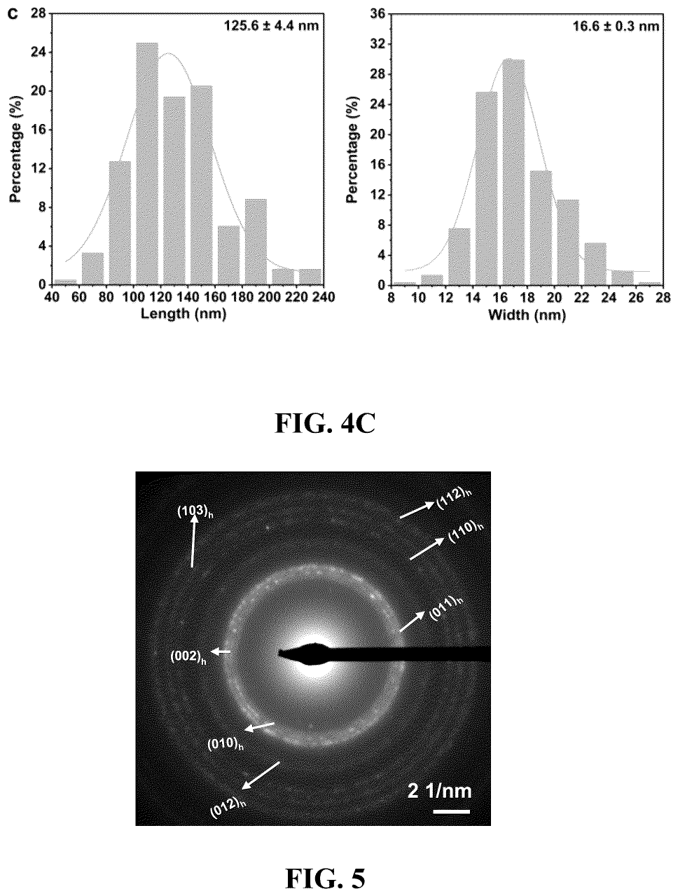

Referring to FIGS. 4A-4C, the average length and middle-width of individual nanobranches were 125.6±4.4 nm and 16.6±0.3 nm, respectively.

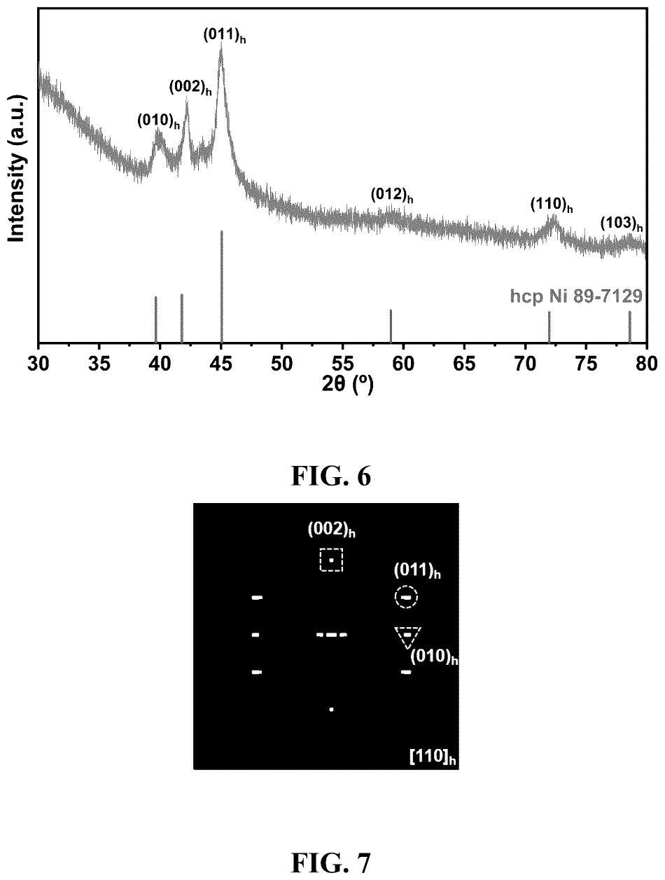

The unconventional hcp phase was also identified by the characteristic diffraction rings in the selected-area electron diffraction (SAED) pattern of IrNi NBs (FIG. 5). Meanwhile, the hcp phase was further confirmed by the powder X-ray diffraction (XRD) pattern (FIG. 6). Furthermore, the unconventional hcp phase was confirmed by the corresponding fast Fourier transform (FFT) pattern of hcp phase along the [110]ₕ zone axis (FIG. 7).

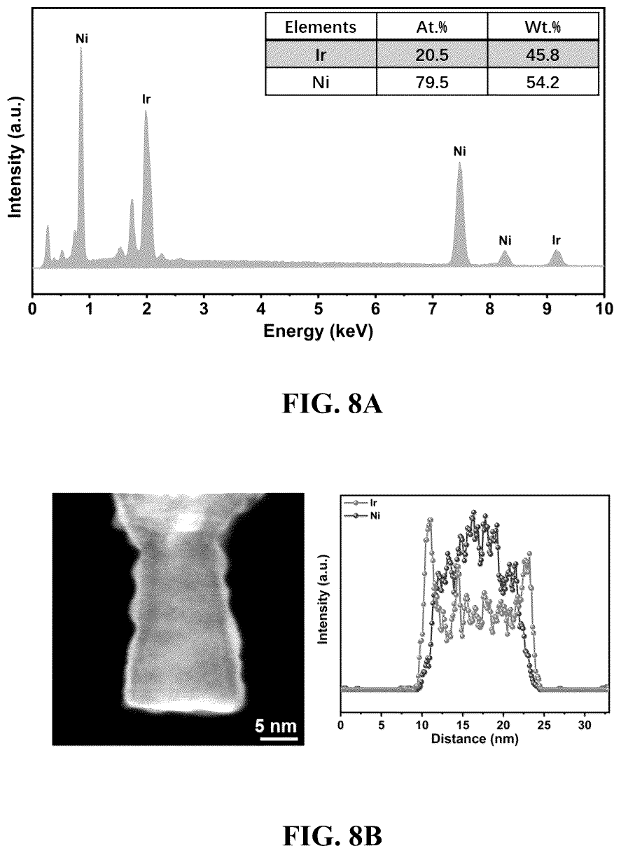

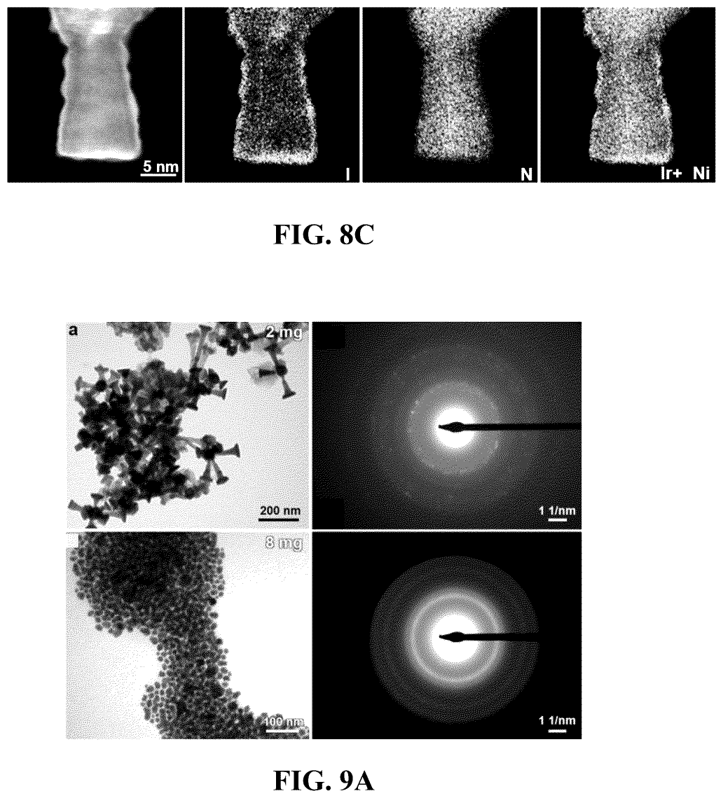

The energy dispersion X-ray spectroscopy (EDS) result showed that the atomic ratio of Ir was 20.5 at %, and the atomic ratio of Ni was 79.5 (FIG. 8A). The EDS line scanning and elemental mapping investigations unraveled the alloy structure of hcp IrNi NBs with a Ni-rich core and Ir-rich shell (FIGS. 8B-8C), which was well consistent with the observation that the lattice spacing at the shell region was larger than that at the core area.

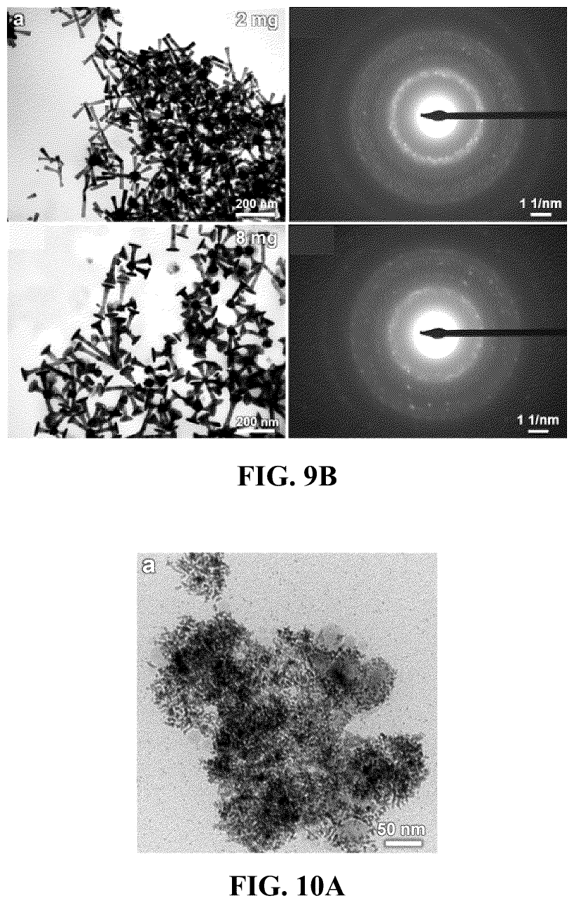

Meanwhile, it was found that when replacing Ir(acac)₃ with IrCl₃(aq) or changing Ni(acac)₂ to NiCl₂·6H₂O, the hcp IrNi NBs could still be obtained. Besides, the morphology and crystal phase may be greatly affected by the dosage of Ir(acac)₂ within the reaction system. Specifically, reducing the dosage of Ir(acac)₃ by half resulted in the formation of hcp IrNi NBs with low uniformity, while doubling the dosage generated fcc IrNi nanoparticles (FIG. 9A). In contrast, the dosage of Ni(acac)₂ had little impact on the morphology and crystal phase of products (FIG. 9B).

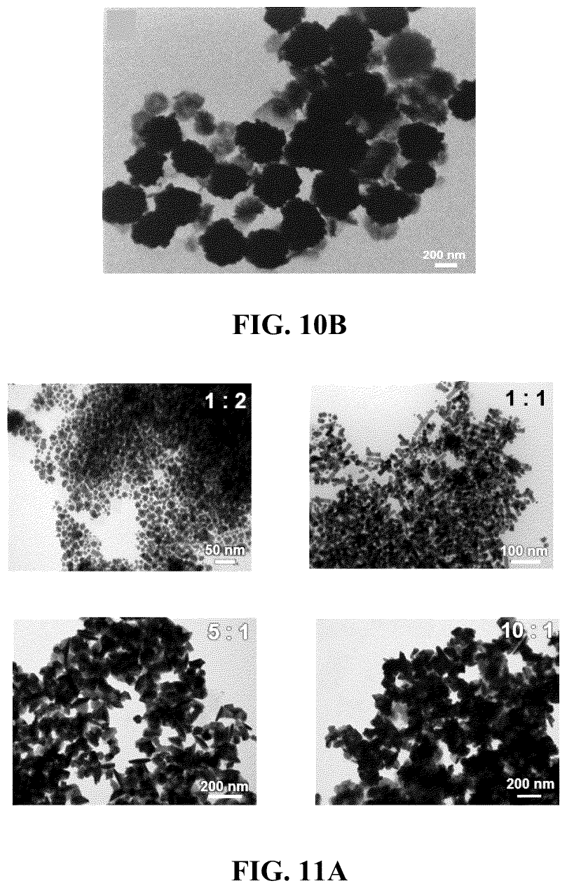

The co-reduction of Ir and Ni precursors was crucial for the successful synthesis of hcp nanobranches. In the absence of Ni(acac)₂, the yield of products was very little. That would be attributed to the strong coordination abilities of the amino and carboxylic acid functional groups in OAm and OA to Ir³⁺, which significantly reduced the reduction potential of Ir³⁺/Ir and slowed down the reduction rate of Ir³⁺. On the other hand, without adding Ir(acac)₃, irregular Ni nanoparticles were formed (FIGS. 10A-10B). These results suggested that the co-reduction of Ir and Ni was prerequisite for hcp IrNi NBs.

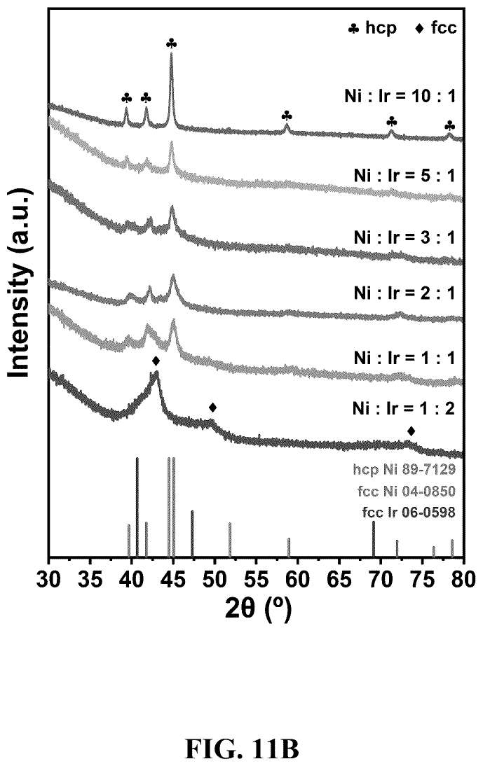

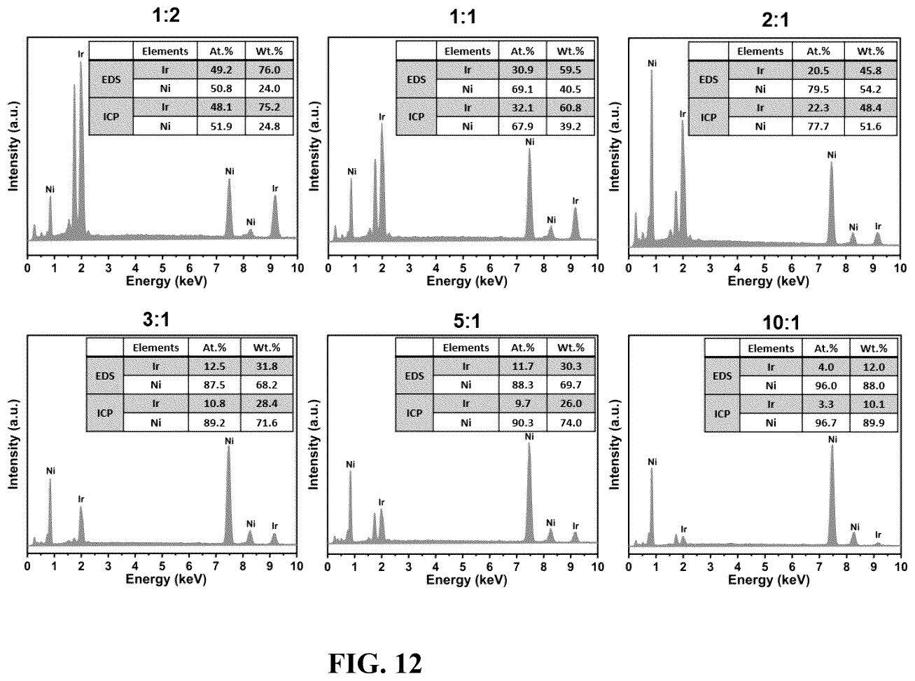

Moreover, the morphology was changed from nanobranches to nanoparticles by decreasing the feeding atomic ratio of Ni/Ir (FIGS. 11A-11B). When the feeding atomic ratio of Ni:Ir was 1:2, irregular nanoparticles with fcc phase were obtained. Referring to FIG. 12, the ultimate Ir atomic percentage was 49.2%. With increasing the atomic ratio from 1:1 to 10:1, the Ir contents of products gradually decreased (from 30.9% to 4.0%) but with pure hcp phase. When the feeding atomic ratios were 2:1 and 3:1, the nanobranches could be obtained. The corresponding atomic ratios of Ir/Ni were 20.5/79.5 and 12.5/87.5, respectively. These results indicated that the feeding atomic ratio of metal precursors was of great significance for the synthesis of hcp IrNi NBs.

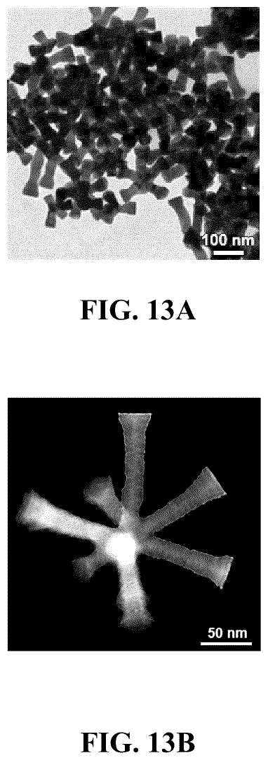

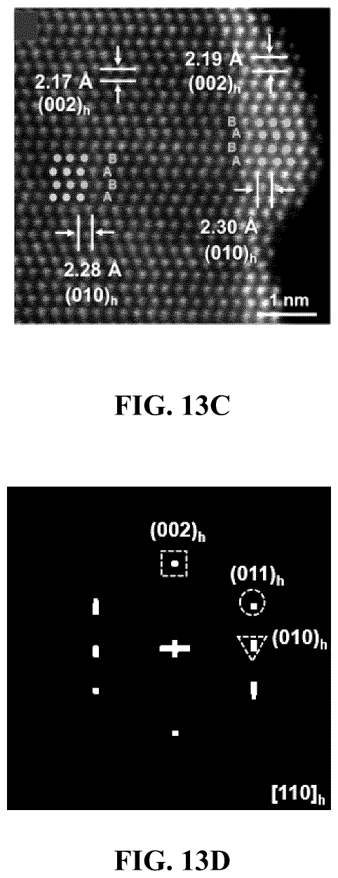

The hcp IrRhNi NBs were prepared by using the same method. TEM and HAADF-STEM images showed that the obtained IrRhNi NBs were assembled by multiple rodlike nanobranches with a core-shell structure (FIGS. 13A-13C). The measured lattice spacings of 2.17 (2.19) and 2.28 (2.30) Å were assigned to (002)ₕ and (010)ₕ facets of hcp phase at the core (shell) sites, respectively. The corresponding FFT pattern matched well with the diffraction pattern of hcp phase along the [110]ₕ zone axis (FIG. 13D).

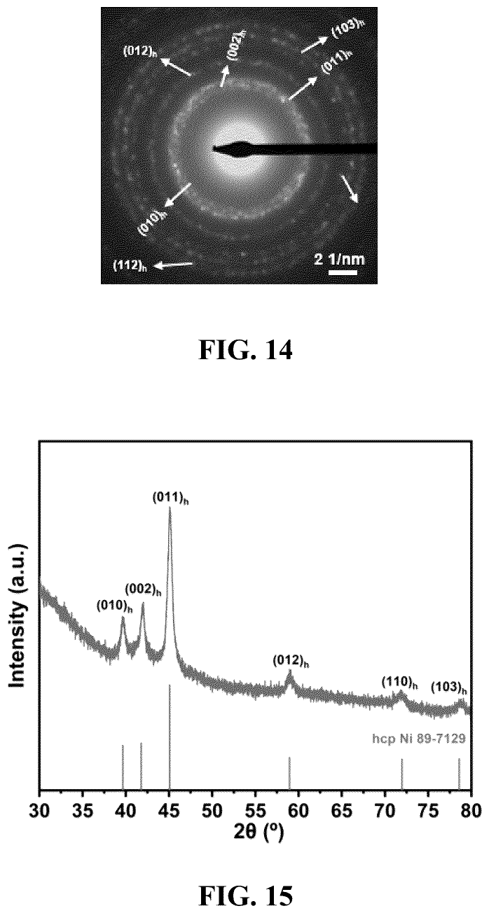

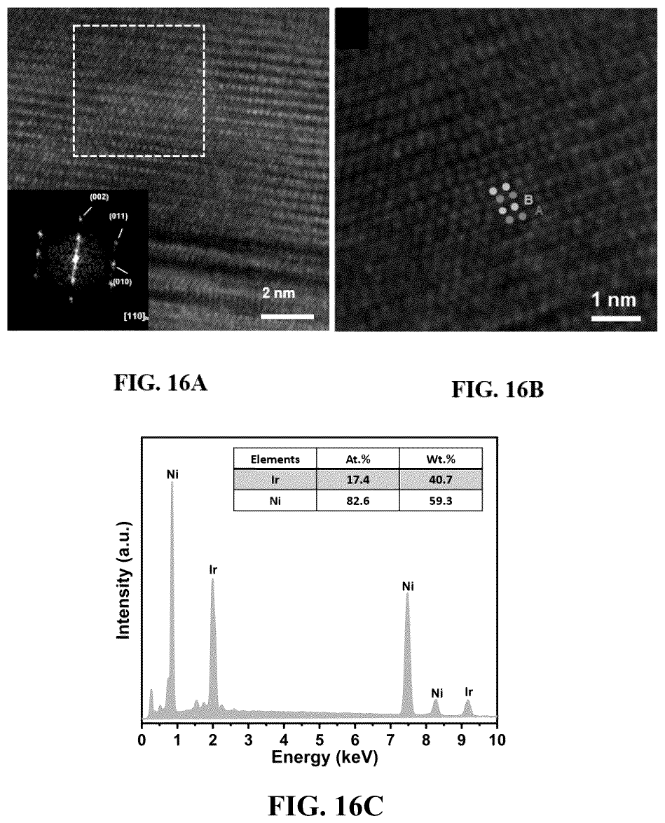

The SAED pattern of IrRhNi NBs could be assigned to the hcp phase (FIG. 14), which was also determined by the XRD pattern (FIG. 15). The FFT pattern and the characteristic stacking sequence of “AB” further verified the hcp structure (FIGS. 16A-16B). The Ir/Ni atomic ratio was determined to be 17.4/82.6 (FIG. 16C).

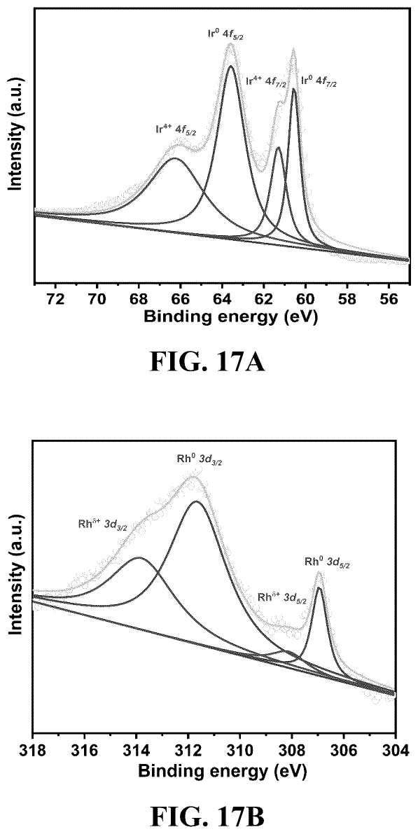

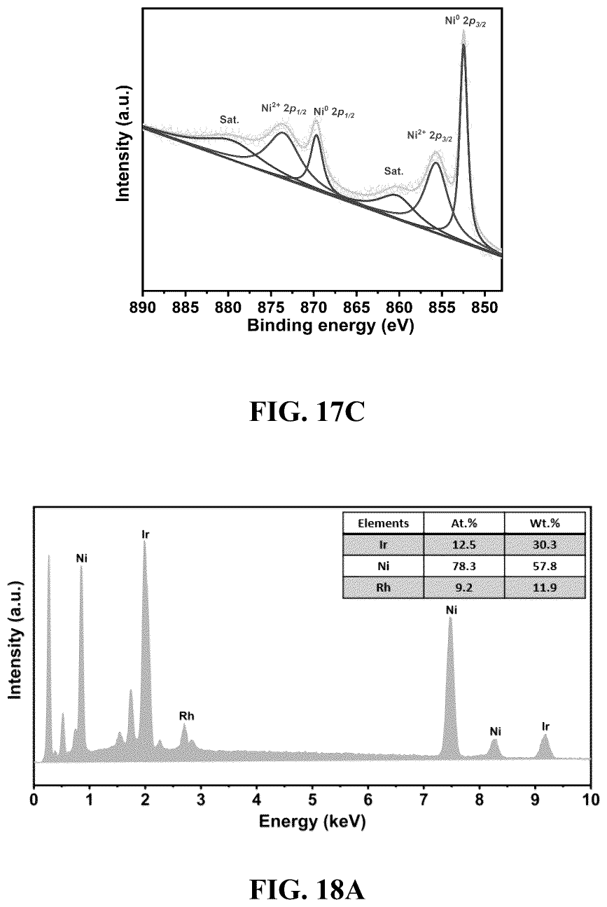

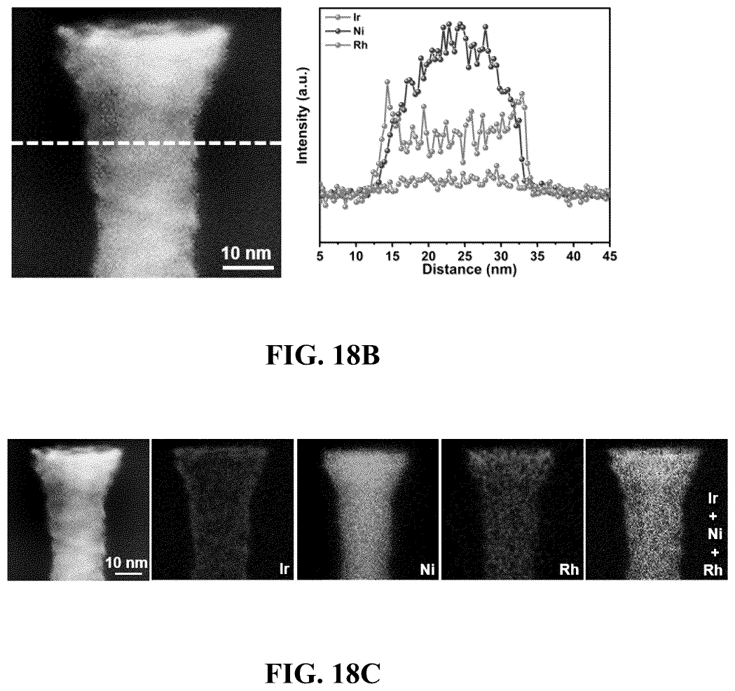

The XPS spectra confirmed the dominant metallic states of Ir, Rh, and Ni in hcp IrRhNi NBs (FIGS. 17A-17C). The EDS spectrum demonstrated that the atomic ratio of Ir/Rh/Ni is 12.5/78.3/9.2 (FIG. 18A). Moreover, the alloy structure with Ni-rich core and Ir-rich shell for the obtained hcp IrRhNi NBs was identified by the EDS line scanning and elemental mapping results (FIGS. 18B-18C).

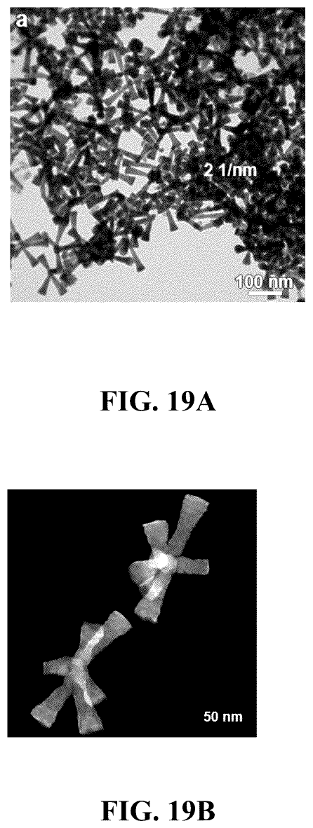

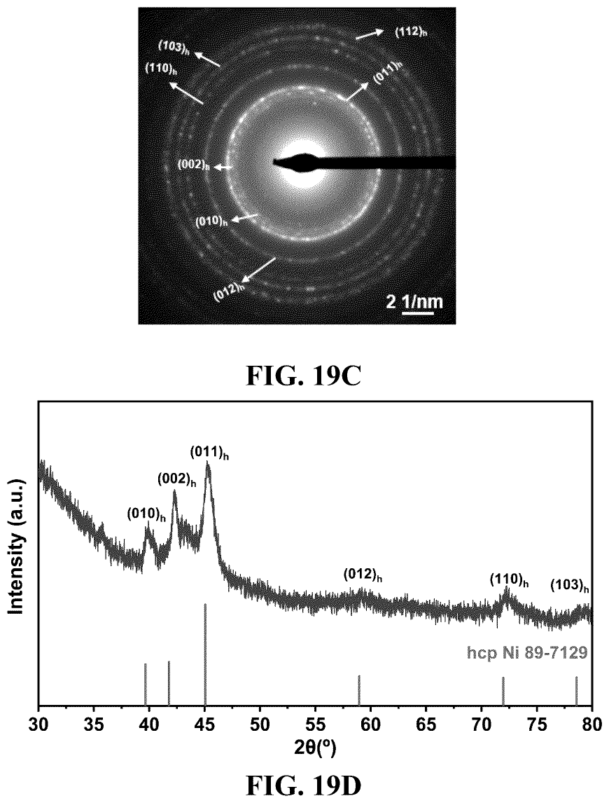

In addition, the hcp IrFeNi NBs could also be prepared by replacing the metal precursor of Rh(acac)₃ with Fe(acac)₃. TEM and HAADF-STEM images exhibited that the obtained IrFeNi nanostructures possessed a similar morphology with IrNi and IrRhNi NBs (FIGS. 19A-19B). The hcp IrFeNi NBs were confirmed by both SAED and XRD patterns (FIGS. 19C-19D).

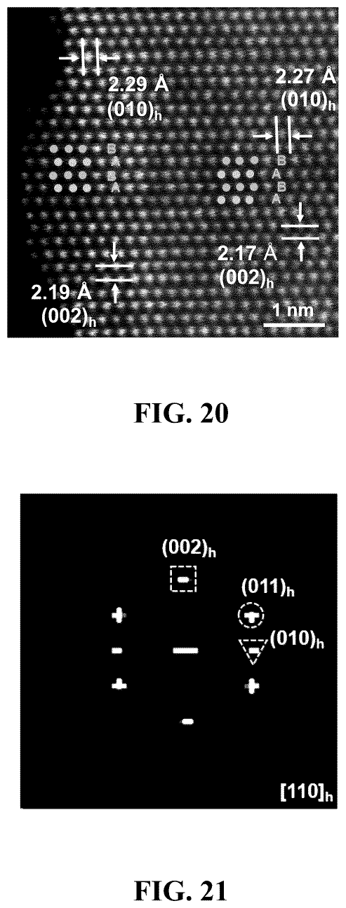

Moreover, at both the core and shell sites, the atomic-resolution HAADF-STEM images clearly showed the characteristic atomic arrangement of hcp phase (FIG. 20). The measured lattice spacings of 2.17 (2.19) and 2.27 (2.29) Å were ascribed to (002)ₕ and (010)ₕ facets of hcp phase at the core (shell) sites, respectively. The corresponding FFT pattern was also well assigned to the hcp phase along the [110]ₕ zone axis (FIG. 21).

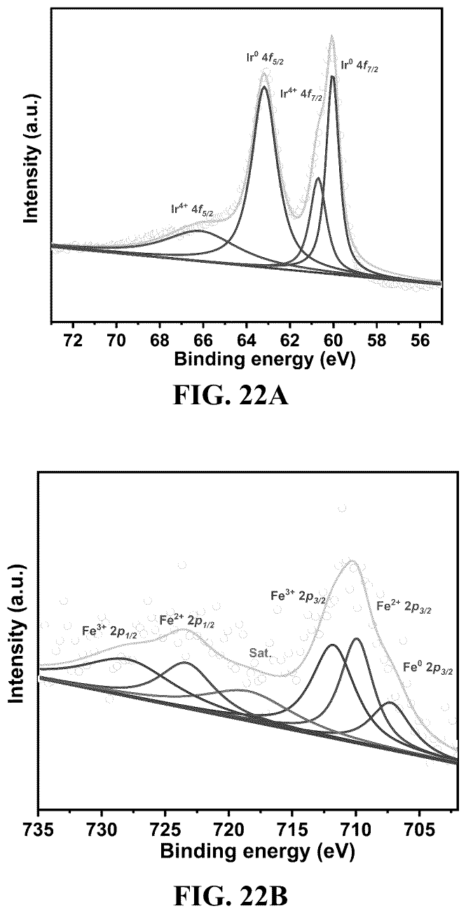

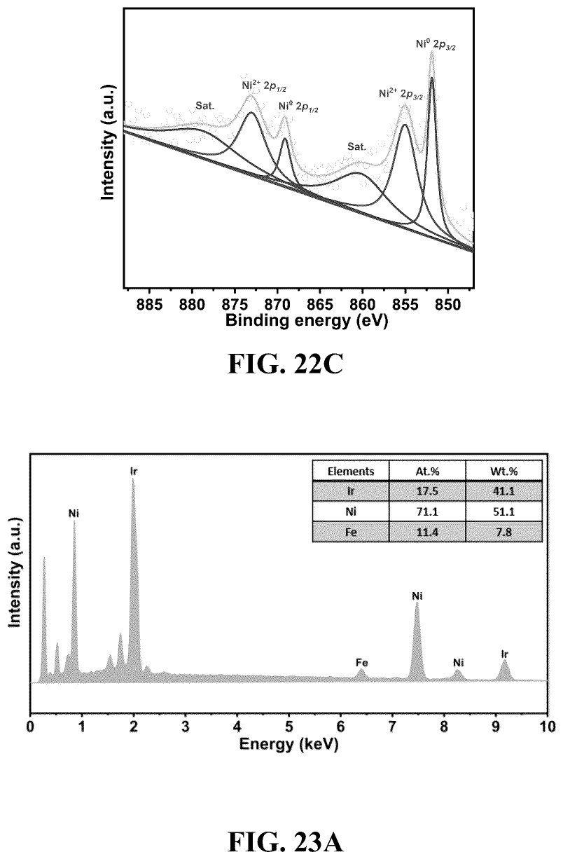

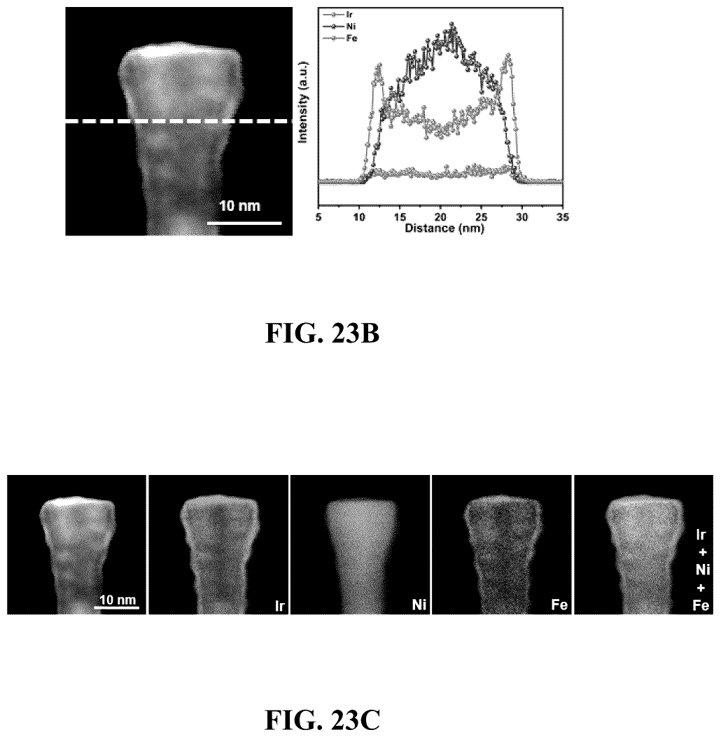

The main metallic states of Ir, Fe, and Ni within IrFeNi NBs were identified by XPS spectra (FIGS. 22A-22C). The EDS spectrum demonstrated that the atomic ratio of Ir/Fe/Ni is 17.5/71.1/11.4 (FIG. 23A). In addition, the EDS line scanning and elemental mapping characterizations revealed that the alloys structure of hcp IrFeNi NBs, which also possessed an Ir-rich shell and Ni-rich core (FIGS. 23B-23C).

### Example 4

### Comparison Between Hcp IrNi NBs and Fcc IrNi NPs

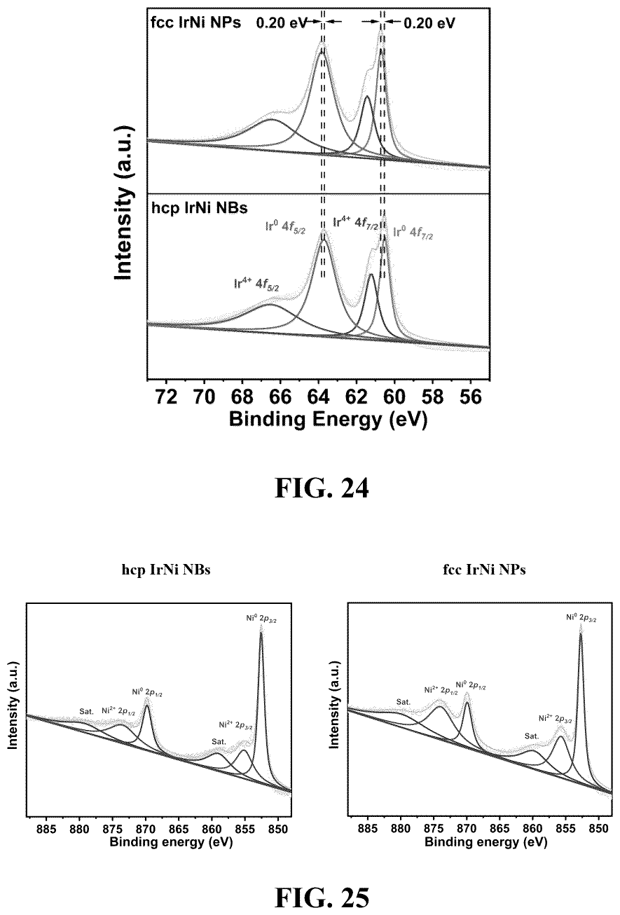

Besides hcp IrNi NBs, the common fcc IrNi NPs with a similar atomic ratio of Ir/Ni to hcp IrNi NBs were also prepared. The electronic structures of hcp IrNi NBs and fcc IrNi NPs were analyzed by XPS. As shown in FIG. 24, Ir mainly existed in the metallic state with a slight oxidation of surface atoms in both hcp IrNi NBs and fcc IrNi NPs. Compared to fcc IrNi NPs, the Ir 4f peak positions of hcp IrNi NBs showed a negative shift by about 0.20 eV, indicating the higher electron density of Ir and stronger interaction between Ir and Ni. The Ni 2p XPS spectra of both samples suggested that the dominant valance of Ni was metallic state, which should benefit from the IrNi alloy structure (FIG. 25).

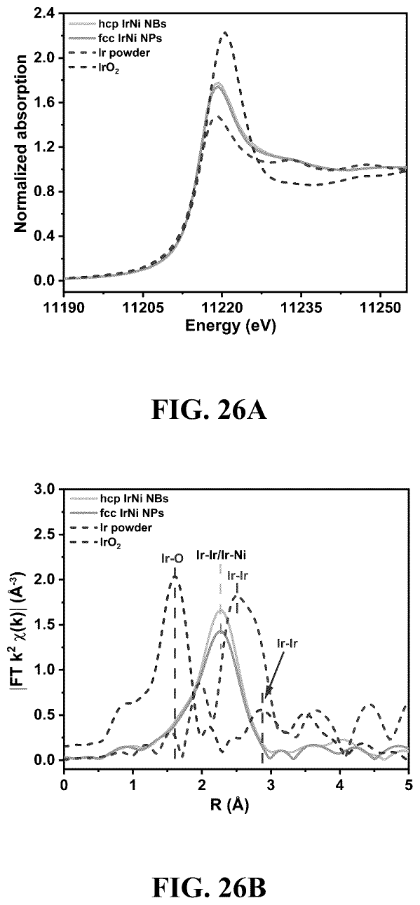

XAS was further utilized to study the electronic structures and local coordination environments of as-synthesized hcp IrNi NBs and fcc IrNi NPs. In the Ir L₃-edge XANES spectra, the white line intensities of hcp IrNi NBs and fcc IrNi NPs were close to that of Ir powder, but far below that of IrO₂, suggesting that Ir mainly adopted the metallic state but with a slight oxidation (FIG. 26A). FIG. 26B showed the k²-weighted Fourier-transform Ir L₃-edge extended X-ray absorption fine structure (EXAFS) spectra. There was one dominant peak located at around 2.51 Å for Ir powder, which was assigned to the Ir—Ir scattering path. While the dominant peaks at about 2.27 Å for hcp IrNi NBs and fcc IrNi NPs were ascribed to the Ir—Ir or Ir—Ni scattering paths. The shorter Ir—Ir or Ir—Ni bond distances in hcp IrNi NBs and fcc IrNi NPs than that in the pure Ir powder was attributed to the formation of IrNi nanostructures.

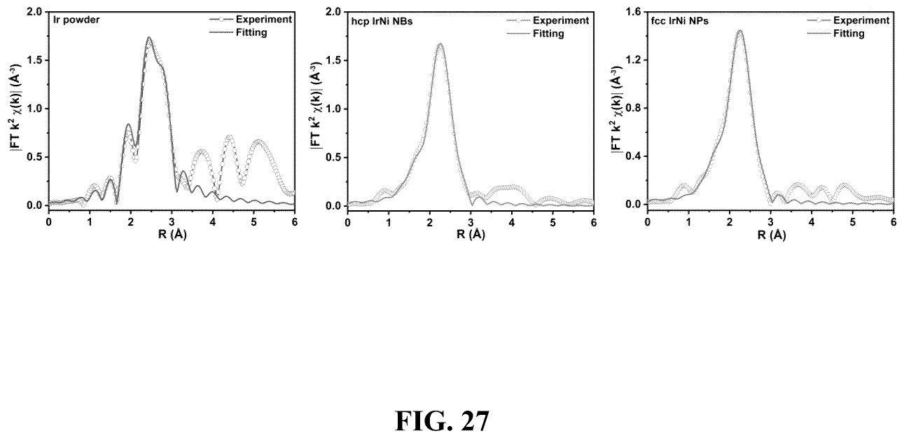

Besides, no obvious Ir—O scattering paths were observed, which further indicated the main metallic states of Ir in both hcp IrNi NBs and fcc IrNi NPs. The fitting results showed that hcp IrNi NBs and fcc IrNi NPs had the same bond distances of Ir—Ir and Ir—Ni (Table 1 and FIG. 27). The coordination numbers (C.N.) of Ir—Ir and Ir—Ni in hcp IrNi NBs were 5.8 and 4.9, respectively, they were similar to those in fcc IrNi NPs, suggesting the substantial alloying of Ir with Ni. These results collaborated that Ir demonstrated a similar coordination environment in hcp IrNi NBs and fcc IrNi NPs.

TABLE 1
Summary of the Ir K-edge EXAFS fitting results
of Ir powder, hcp IrNi NBs, and fcc IrNi NPs

| | Scattering | | | | ΔE₀ | |
|---|---|---|---|---|---|---|
| Samples | paths | R (Å) | C.N. | σ² (Å²) | (eV) | R-factor |
| Ir powder | Ir—Ir | 2.72 | 12* | 0.004 | 7.9 | 0.007 |
| hcp IrNi NBs | Ir—Ir | 2.65 | 5.8 | 0.006 | 6.6 | 0.002 |
| | Ir—Ni | 2.57 | 4.9 | 0.006 | 6.6 | |
| | Ir—O | 1.96 | 1.0 | 0.006 | 6.5 | |
| fcc IrNi NPs | Ir—Ir | 2.65 | 5.6 | 0.007 | 7.0 | 0.002 |
| | Ir—Ni | 2.57 | 4.3 | 0.007 | 7.0 | |
| | Ir—O | 1.96 | 1.0 | 0.007 | 7.0 | |

Note:
Fittings were obtained using k²-weighted R-space spectra with a k-range of 3.0-12 Å⁻¹, s₀² = 0.7 and a R-range of 1.0-3.0 Å; R is the interatomic distance (the bond length between center atoms and surrounding coordination atoms); C.N. is the coordination number; σ² is the Debye-Waller factor (a measure of thermal and static disorder in absorber-scatterer distances); ΔE₀ is the edge-energy shift (the difference between the zero kinetic energy value of the sample and that of the theoretical model) used to align the theoretical calculated spectrum to the energy grid of the measured spectrum; The uncertainty of fitting parameters: C.N., ±20%, R, ±1%; σ², ±20%, ΔE₀, ±20%. R factor was used to evaluate the goodness of the fitting.
*These values were fixed during the EXAFS fitting, based on the known structures of Ir powder.

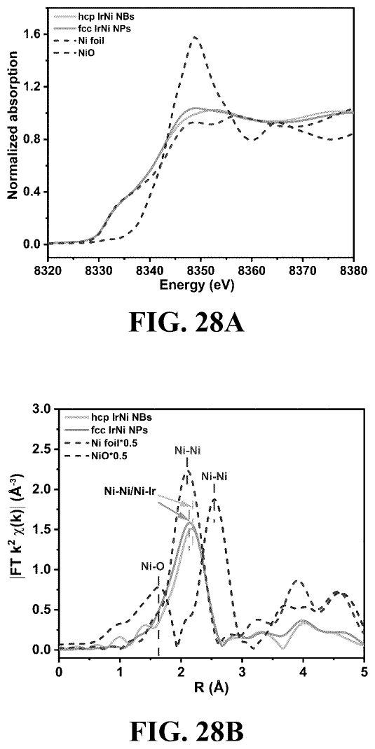

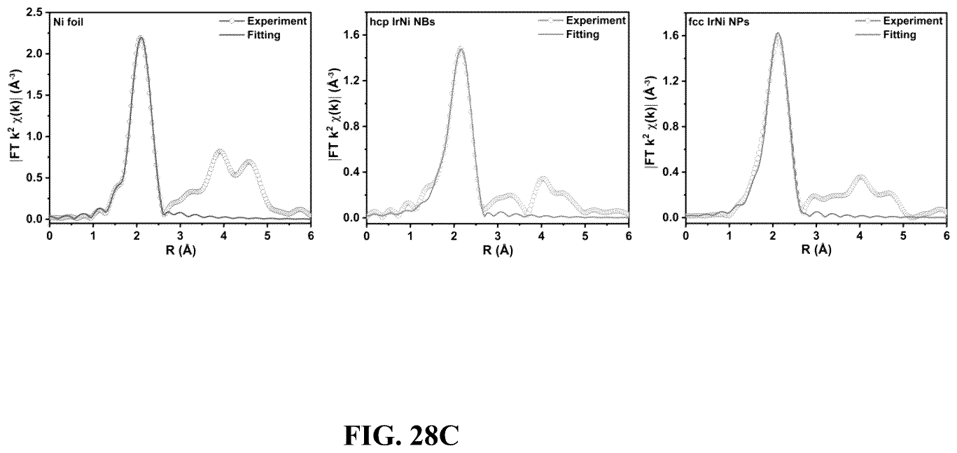

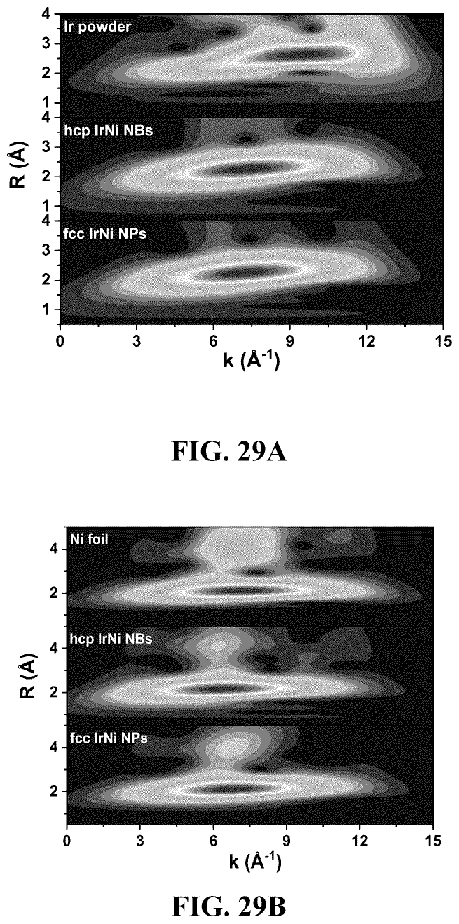

Referring to FIG. 28A, in the Ni K-edge XANES spectra, the white line intensities of hcp IrNi NBs and fcc IrNi NPs were slightly higher than that of Ni foil but much lower than that of NiO, indicating the main metallic state of Ni in both samples. As shown in the k²-weighted Ni K-edge EXAFS spectra, no obvious Ni—O scattering paths appeared in these two samples, and the position of the dominant peak in fcc IrNi NPs and hcp IrNi NBs was close to that in Ni foil, suggesting the dominant metallic state of Ni in both nanostructures (FIG. 28B). The fitting results showed that the C.N. of Ni—Ni was much higher than that of Ni—Ir in fcc IrNi NPs and hcp IrNi NBs, which meant that a small amount of Ni coordinated with Ir to form the IrNi alloy structure (Table 2 and FIG. 28C). These results agree well with the observation of the unique structure with Ni-rich core and Ir-rich shell by the TEM and EDS. However, the larger C.N. of Ni—Ir in hcp IrNi NBs over fcc IrNi NPs suggested the higher alloy degree of Ni in hcp IrNi NBs. Meanwhile, the larger bond distance of Ni—Ni in hcp IrNi NBs (2.58 Å) than those in Ni foil with fcc phase (2.48 Å) and fcc IrNi NPs (2.51 Å) elucidated the successful formation of hcp structure. The intensity maxima of wavelet transforms (WTs) of Ir L₃-edge EXAFS spectra of fcc IrNi NPs and hcp IrNi NBs were similar with each other, and showed downward shift than Ir powder, suggesting the formation of the IrNi alloy structure (FIG. 29A). In the Ni K-edge WT, the intensity maxima of fcc IrNi NPs and hcp IrNi NBs were close to that of Ni foil, which further identified the metallic state of Ni (FIG. 29B).

TABLE 2
Summary of the Ni K-edge EXAFS fitting results
of Ni foil, hcp IrNi NBs, and fcc IrNi NPs.

| | Scattering | | | | ΔE₀ | |
|---|---|---|---|---|---|---|
| Samples | paths | R (Å) | C.N. | σ² (Å²) | (eV) | R-factor |
| Ni foil | Ni—Ni | 2.48 | 12* | 0.005 | −5.6 | 0.005 |
| hcp IrNi NBs | Ni—Ni | 2.58 | 8.1 | 0.011 | −6.1 | 0.011 |
| | Ni—Ir | 2.57 | 1.4 | 0.011 | −6.1 | |
| fcc IrNi NPs | Ni—Ni | 2.51 | 5.7 | 0.008 | −6.7 | 0.015 |
| | Ni—Ir | 2.57 | 0.5 | 0.008 | −6.6 | |

Note:
Fittings were obtained using k²-weighted R-space spectra with a k-range of 3.0-12 Å⁻¹, s₀² = 0.78 and a R-range of 1.0-3.0 Å; R is the interatomic distance (the bond length between center atoms and surrounding coordination atoms); C.N. is the coordination number; σ² is the Debye-Waller factor (a measure of thermal and static disorder in absorber-scatterer distances); ΔE₀ is the edge-energy shift (the difference between the zero kinetic energy value of the sample and that of the theoretical model) used to align the theoretical calculated spectrum to the energy grid of the measured spectrum; The uncertainty of fitting parameters: C.N., ±20%, R, ±1%; σ², ±20%, ΔE₀, ±20%. R factor was used to evaluate the goodness of the fitting.
*These values were fixed during the EXAFS fitting, based on the known structures of Ni foil.

### Example 5

### Electrochemical NO₂RR Performance

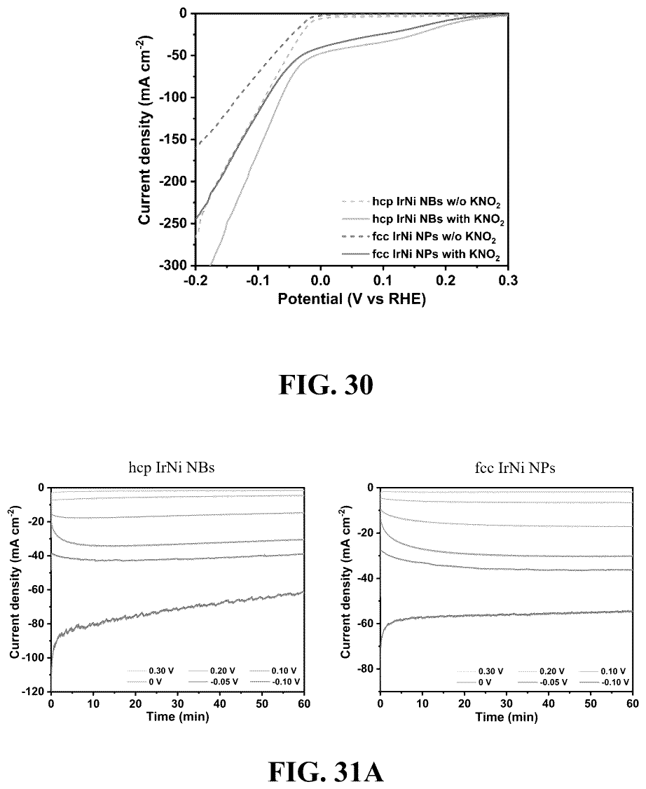

In this example, the as-prepared hcp IrNi NBs and fcc IrNi NPs were utilized as catalysts in electrocatalytic NO₂RR. The electrocatalytic performance was tested in a standard H-type cell by using the electrolyte containing 1 M KOH and 0.1 M KNO₂. As shown in FIG. 30, in the presence of KNO₂, the hcp IrNi NBs delivered a much higher current density, suggesting their better NO₂RR performance over fcc IrNi NPs.

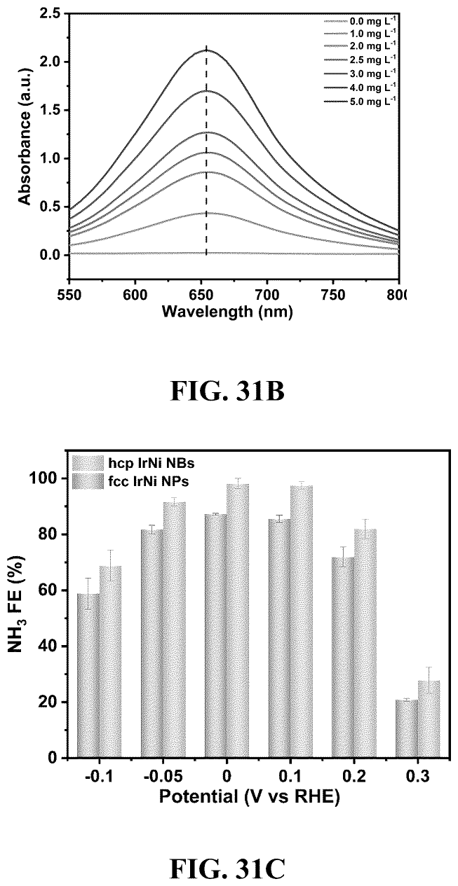

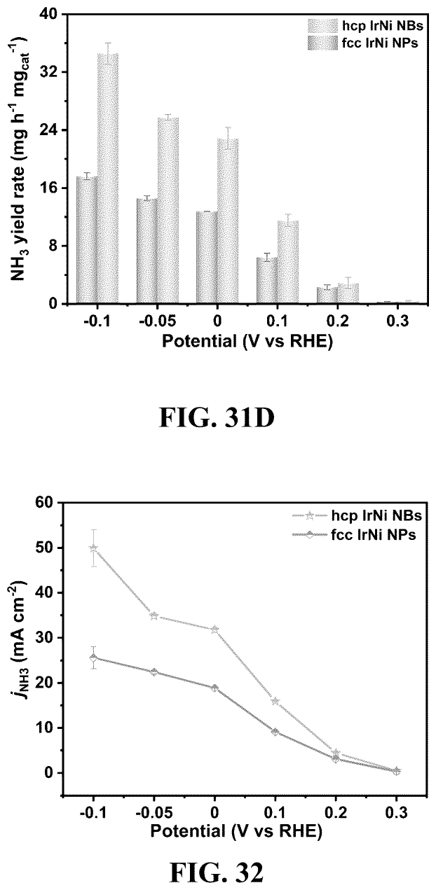

Chronoamperometry measurements with the potential range of 0.3 to −0.1 V (vs RHE) were further conducted to evaluate the NO₂RR performance of hcp IrNi NBs and fcc IrNi NPs (FIGS. 31A-31B). The hcp IrNi NBs demonstrated the highest NH₃ FE of 98.2% at 0 V (vs RHE), which was much larger than fcc IrNi NPs (87.2%). Notably, the NH₃ FE of hcp IrNi NBs was well maintained above 90% at a wide potential range from 0.1 to −0.05 V (vs RHE) (FIG. 31C).

Meanwhile, hcp IrNi NBs also demonstrated a much higher NH₃ yield rate, and achieved the highest value of 34.6 mg h⁻¹ mg_{cat}⁻¹ (or 75.5 mg h⁻¹ mg_{Ir}⁻¹) at −0.1 V (vs RHE), which was 1.97 (1.84) times that of fcc IrNi NPs (17.6 mg h⁻¹ mg_{cat}¹ (or 41.0 mg h⁻¹ mg_{Ir}⁻¹)) (FIG. 31D). Correspondingly, hcp IrNi NBs exhibited a superior partial current density of NH₃ over that of fee IrNi NPs, and reached the maximum value of 49.9 mA cm⁻³ at −0.1 V (vs RHE) (FIG. 32).

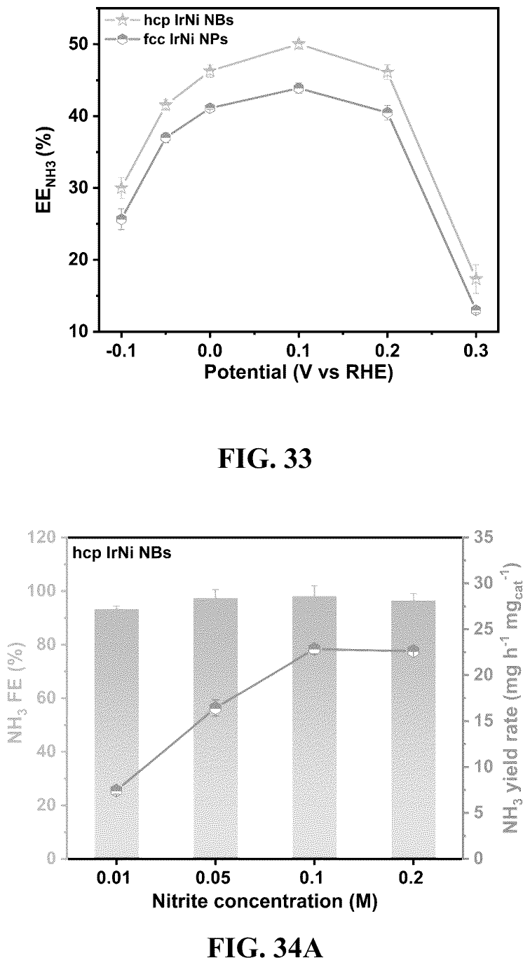

In addition, hPp IrNi NBs also achieved a much higher energy efficiency (EE) in the whole potential range, with the highest value of 50.1% at 0.1 V (vs RHE) (FIG. 33). Table 3 highlighted that hcp IrNi NBs exhibited outstanding NH₃ FE, EE and yield rate at low overpotentials, surpassing most of the reported catalysts for NO₂RR.

TABLE 3
Comparison of the electrochemical NO₂RR performance of hcp IrNi NBs with the other reported electrocatalysts.

| | | | NH₃ | | | | |
|---|---|---|---|---|---|---|---|
| | | | Faradaic | Energy | | | |
| | | Potential | efficiency | efficiency | NH₃ | | |
| Catalysts | Electrolytes | (V vs RHE) | (%) | (%) | yield rate | | Note |
| hcp IrNi NBs | 1M KOH + | 0 | 98.2 | 50.0 | 22.8 | mg h⁻¹ mg_{cat}⁻¹ | The present |
| | 0.1M KNO₂ | −0.1 | 68.8 | | 34.6 | mg h⁻¹ mg_{cat}⁻¹ | invention |
| hcp IrNi NBs | 1M KOH + | 0 | 97.5 | 49.1 | 16.4 | mg h⁻¹ mg_{cat}⁻¹ | The present |
| | 0.05M KNO₂ | −0.1 | 60.8 | | 21.5 | mg h⁻¹ mg_{cat}⁻¹ | invention |
| hcp IrNi NBs | 1M KOH + | 0 | 93.3 | 47.3 | 7.4 | mg h⁻¹ mg_{cat}⁻¹ | The present |
| | 0.01M KNO₂ | −0.1 | 36.0 | | 10.1 | mg h⁻¹ mg_{cat}⁻¹ | invention |
| hcp IrNi NBs | 1M KOH + | 0 | 96.6 | 49.0 | 22.6 | mg h⁻¹ mg_{cat}⁻¹ | The present |
| | 0.2M KNO₂ | −0.1 | 69.7 | | 31.9 | mg h⁻¹ mg_{cat}⁻¹ | invention |

NO₂RR in alkaline solution

| | | | | | | | |
|---|---|---|---|---|---|---|---|
| CuFe-450 | 1M KOH + | −0.6 | 93.4 | 29.6 | 40.4 | mg h⁻¹ cm⁻² | Prior art |
| | 0.1M NO₂^{_{−}} | | | | | | |
| Ni₂P | 1M NaOH + | 0 | 92.6 | 43.7 | 12.4 | mg h⁻¹ cm⁻² | |
| | 0.1M NaNO₂ | | | | | | |
| TiO₂₋ₓ | 0.1M NaOH + | −0.7 | 92.7 | 27.9 | 7.9 | mg h⁻¹ mg_{cat}⁻¹ | |
| nanobelt | 0.1M NaNO₂ | | | | | | |
| array | | | | | | | |
| V—TiO₂/TP | 0.1M NaOH + | −0.6 | 93.2 | 29.5 | 6.97 | mg h⁻¹ cm⁻² | |
| | 0.1M NO₂^{_{−}} | | | | | | |
| Ni—TiO₂/TP | 0.1M NaOH + | −0.5 | 94.89 | 31.8 | 6.72 | mg h⁻¹ cm⁻² | |
| | 0.1M NO₂^{_{−}} | | | | | | |
| CoP@TiO₂ | 0.1M NaOH + | −0.3 | 97.01 | 36.8 | 5.97 | mg h⁻¹ cm⁻² | |

0.1M NO₂^{_{−}}

NO₂RR in neutral solution

| CPO-ILBMB/ | 0.1M PBS (pH | −0.76 | 96.4 | 28.1 | 112.7 | mg h⁻¹ mg_{CPO}⁻¹ | Prior art |
|---|---|---|---|---|---|---|---|
| MW CNT-PEI | 5.0) + 0.05M NO₂^{_{−}} | | | | | | |
| Ni₁Ru single | 0.5M Na₂SO₄ + | −0.6 | 95.9 | 30.4 | 8.3 | mg h⁻¹ cm⁻² | |
| atom alloy | 0.1M NaNO₂ | | | | | | |
| Ru | 0.5M Na₂SO₄ + | −0.5 | 67.1 | 22.5 | 3.7 | mg h⁻¹ cm⁻² | |
| | 0.1M NaNO₂ | | | | | | |
| Ru SA-NC | 1.0M KOH + | −0.4 | 97.8 | 34.8 | 11.73 | mg h⁻¹ cm⁻² | |
| | 0.5M NO₂^{_{−}} | | | | | | |
| Ni₃₅/NC-sd | 0.5M Na₂SO₄ + | −0.4 | 99 | 35.2 | 1.1 | mg h⁻¹ cm⁻² | |
| | 0.1M NaNO₂ | | | | | | |
| Pd/CuO NOs | 0.1M K₂SO₄ + | −1.5 | 91.8 | 19.5 | 0.91 | mg h⁻¹ mg_{cat}⁻¹ | |
| | 0.01M KNO₂ | | | | | | |
| CuFe-450 | 0.1M PBS + | −0.8 | 90.6 | 25.9 | 2.33 | mg h⁻¹ cm⁻² | |
| | 3 mM NO₂^{_{−}} | | | | | | |
| CF@Cu₂O | 0.1M PBS + | −0.6 | 94.2 | 29.9 | 7.5 | mg h⁻¹ cm⁻² | |
| | 0.1M NO₂^{_{−}} | | | | | | |
| FeOOH | 0.1M PBS (pH = | −1.0 | 94.7 | 24.6 | 9.75 | mg h⁻¹ cm⁻² | |
| NTA/CC | 7.0) + 0.1M NO₂⁻ | | | | | | |
| CoFe-NC | 0.1M PBS + | −0.7 | 94.5 | 28.4 | 3.48 | mg h⁻¹ cm⁻² | |
| | 0.1M NaNO₂ | | | | | | |
| Cobaloxime | 0.1M PBS + | −0.5 | 98.4 | 33.0 | 19.3 | mg h⁻¹ mg_{cat}⁻¹ | |
| | 0.1M NaNO₂ | | | | | | |
| C/Co₃O₄ | 0.5M K₂SO₄ + | −0.6 | ~100 | 31.7 | 4.10 | mg h⁻¹ cm⁻² | |
| | 50 mM KNO₂ | | | | | | |
| Cu₃P NA/CF | 0.1M PBS + | −0.5 | 91.2 ± 2.5 | 30.6 | 1.63 | mg h⁻¹ cm⁻² | |
| | 0.1M NaNO₂ | | | | | | |
| P-TiO₂/TP | 0.1M Na₂SO₄ + | −0.6 | 90.6 | 28.7 | 9.52 | mg h⁻¹ cm⁻² | |
| | 0.1M NaNO₂ | | | | | | |
| Ni-NSA-V_{Ni} | 0.2M Na₂SO₄ + | −1.2 V | 88.9 | — | — | | |
| | 200 ppm NaNO₂ | (vs SCE) | | | | | |
| CoP NA/TM | 0.1M PBS (pH = | −0.2 | 90.0 ± 2.3% | 36.5 | 2.261 ± 0.052 | mg h⁻¹ cm⁻² | |
| | 7) + 500 ppm NO₂⁻ | | | | | | |
| MoS₂ NSs | 0.5M Na₂SO₄ + | −0.5 | 93.52 | 31.3 | 1.3 | mg h⁻¹ cm⁻² | |

0.1M NaNO₂

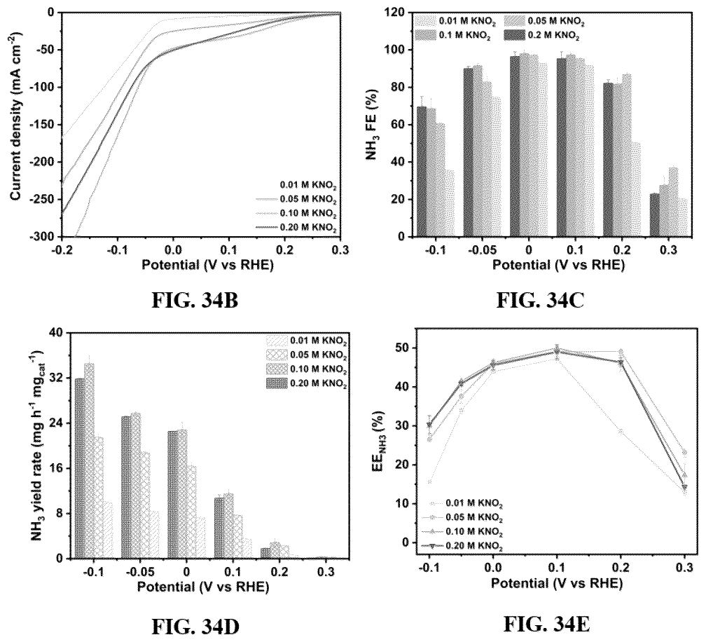

Considering the practical application of nitrite contamination removal, the influence of nitrite concentration on NO₂RR was further explored. Impressively, the superior catalytic performance of hcp IrNi NBs was well maintained over a wide range of nitrite concentrations. In specific, with decreasing the NO₂⁻ concentration from 0.1 M to 0.01 M, the highest NH₃ FE and EE only showed a little decrease from 98.2% to 93.3% and from 50.1% to 47.3%, respectively (FIGS. 34A-34E).

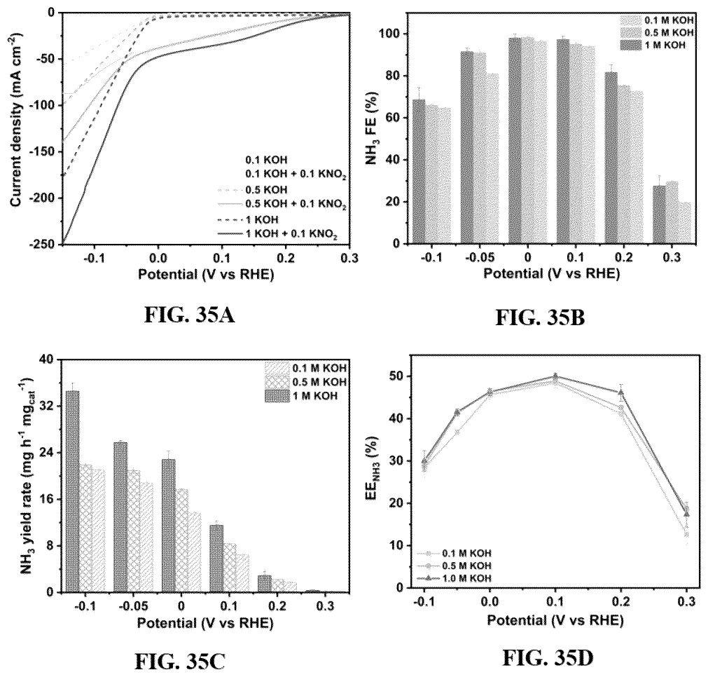

Meanwhile, the highest NH₃ yield rate of 10.1 mg h⁻¹ mg_{cat}¹ could be achieved with 0.01 M NO₂⁻, demonstrating the promising potential for NH₃ production with practical wastewater. When the nitrite concentration increased to 0.2 M, the NH₃ FE, EE, and yield rate showed a slight decrease compared to those of 0.1 M, which may be attributed to the insufficient active hydrogen supply. Besides, the electrochemical NO₂RR performance at different hydroxyl concentrations was also investigated (FIGS. 35A-35D).

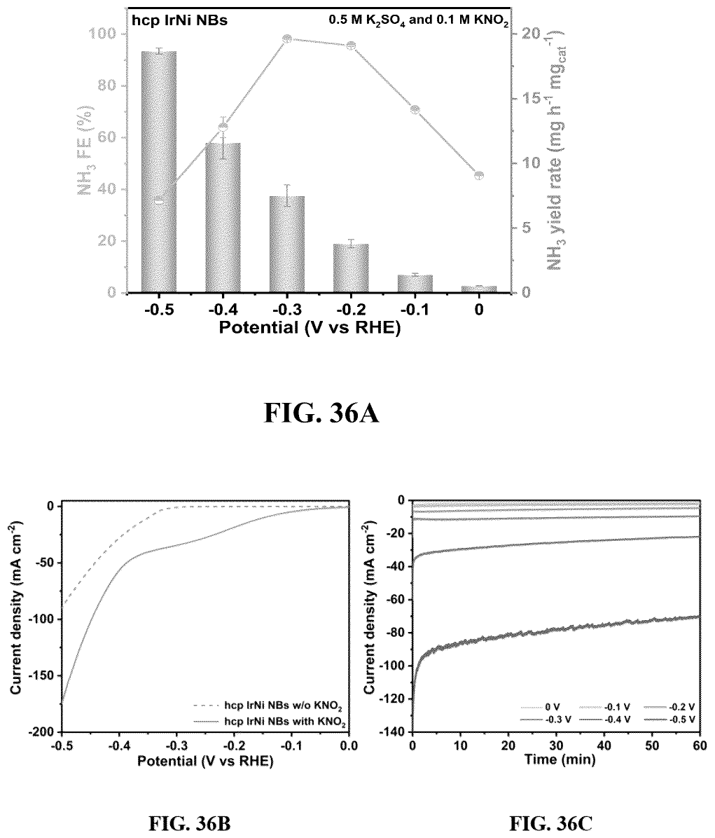

It was observed that the hydroxyl concentration exerted insignificant effect on NH₃ production. In particular, hcp IrNi NBs still exhibited the highest NH₃ FE, EE and yield rate of 96.8%, 48.4% and 21.1 mg h⁻¹ mg_{cat}⁻¹, respectively, when the hydroxyl concentration was as low as 0.1 M. Moreover, in the neutral condition, hcp IrNi NBs achieved the highest NH₃ FE of 98.6% at −0.3 V (vs RHE) as well as the largest NH₃ yield rate of 18.7 mg h⁻¹ mg_{cat}⁻¹ at −0.5 V (vs RHE) (FIGS. 36A-36C). It was found that the pH of electrolyte changed to 11.71 and 12.38 after electrolysis at −0.3 and −0.5 V (vs RHE), respectively. These results revealed the great potential of hcp IrNi NBs as highly efficient catalysts for NH₃ production in NO₂RR under practical conditions.

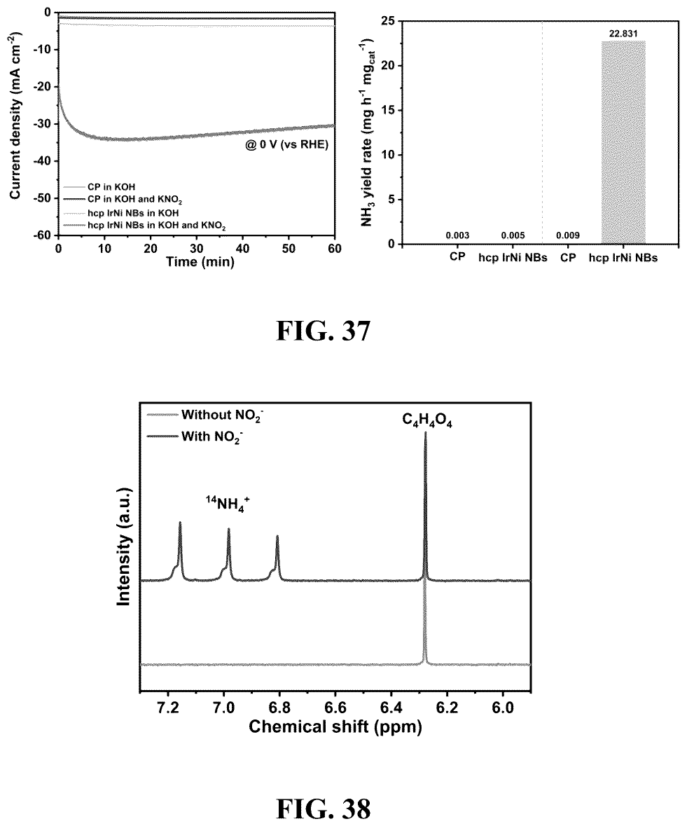

Besides, control experiments were conducted with bare carbon paper and hcp IrNi NBs as the electrodes to confirm the origin of nitrogen source as well as the accuracy of NO₂RR performance measurement. As expected, negligible NH₃ was detected on bare carbon paper in the absence or presence of KNO₂ (FIG. 37). In contrast, the current density and NH₃ yield rate of hcp IrNi NBs were negligible without KNO₂, but increased a lot after introducing KNO₂. Moreover, as shown in the NMR spectrum, no peaks attributed to NH₄⁺ were observed without adding KNO₂ in the electrolyte (FIG. 38).

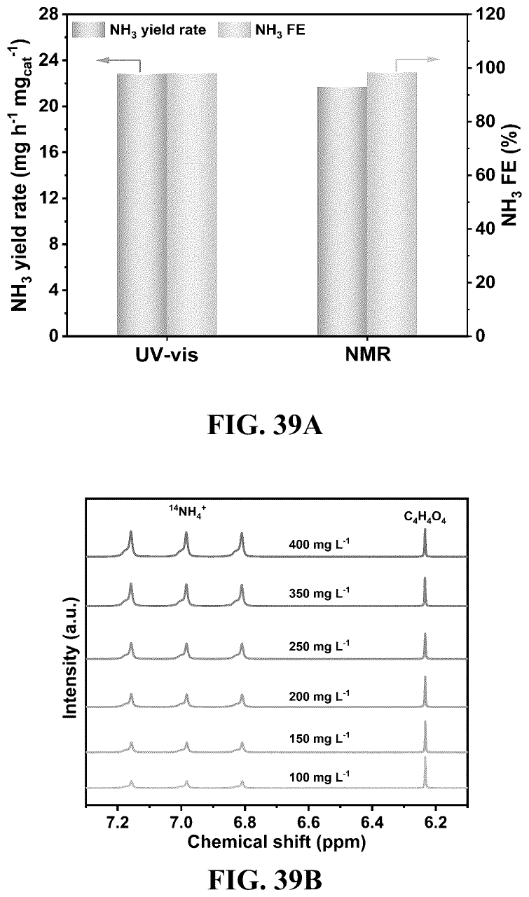

Importantly, the NH₃ FE and yield rate calculated by ultraviolet-visible (UV-vis) spectroscopy were well consistent with those obtained by the NMR method, suggesting the good accuracy and high reliability of the electrochemical results (FIGS. 39A-39B). The NH₃ volatilization in the electrolytes (pH=14) was negligible during the 1 h electrolysis. Besides NH₃, the potential byproducts, including hydrazine (N₂H₄) and H₂, were also detected by UV-vis spectroscopy and gas chromatography, respectively. As the applied potential became more negative to −0.1 V (vs RHE), the FE of N₂H₄ gradually decreased to 0.5%, while that of H₂ increased to 11.5%. At 0 V (vs RHE), the amount of N₂H₄ and H₂ was negligible, which confirmed the high selectivity to NH₃ synthesis.

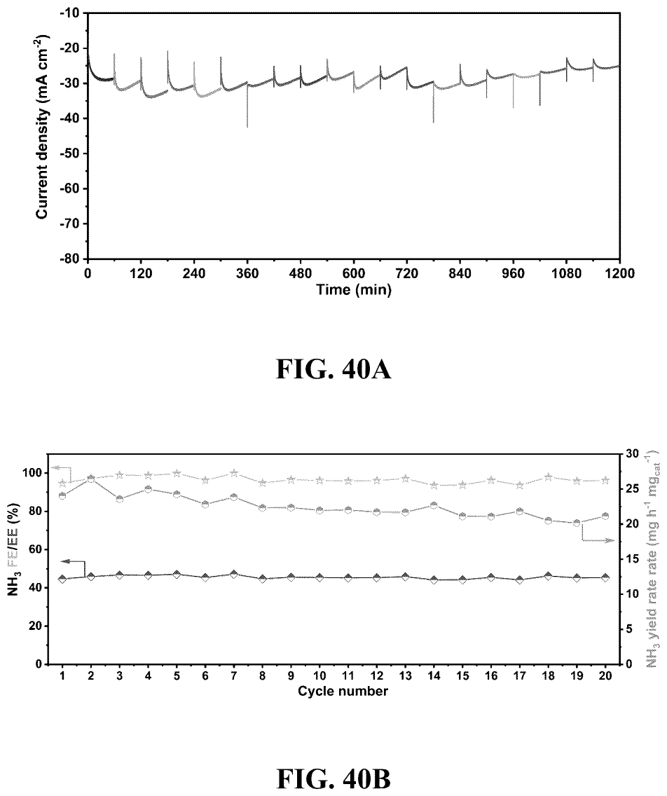

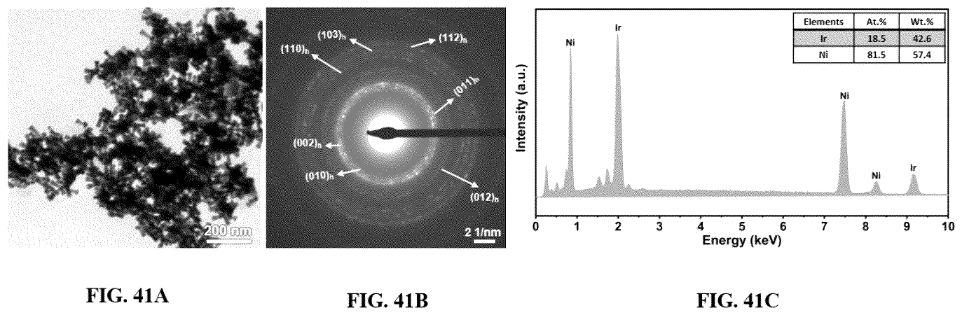

The catalytic stability of hcp IrNi NBs in NO₂RR was evaluated by the consecutive recycling electrolysis at 0 V (vs RHE). During the 20 consecutive electrolysis cycles, the NH₃ FE and yield rate kept stable, suggesting the superior catalytic durability of hcp IrNi NBs toward NO₂RR (FIGS. 40A-40B). Notably, after the stability test, the morphology, composition, and crystal phase of hcp IrNi NBs were well preserved, which was verified by the TEM, SAED, and EDS characterizations (FIGS. 41A-41C). Moreover, the core-shell structure composed by Ni-rich core and Ir-rich shell were well maintained. All the above results confirmed the superior catalytic stability of unconventional hcp IrNi NBs in electrocatalytic NO₂RR.

### Example 6

### Mechanism

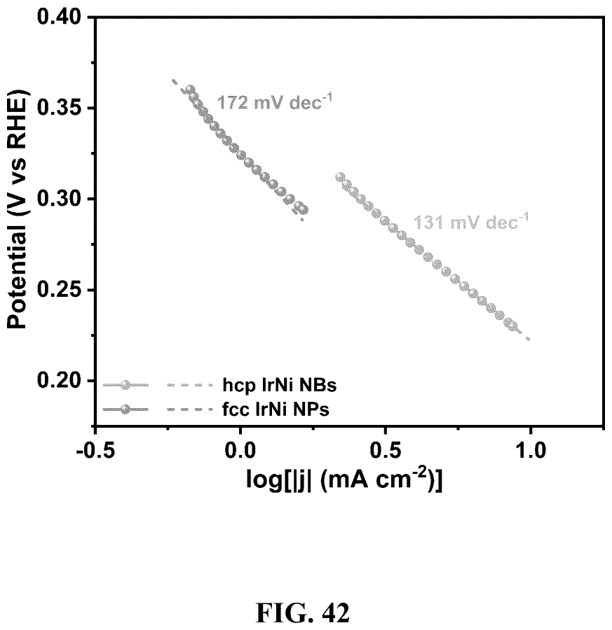

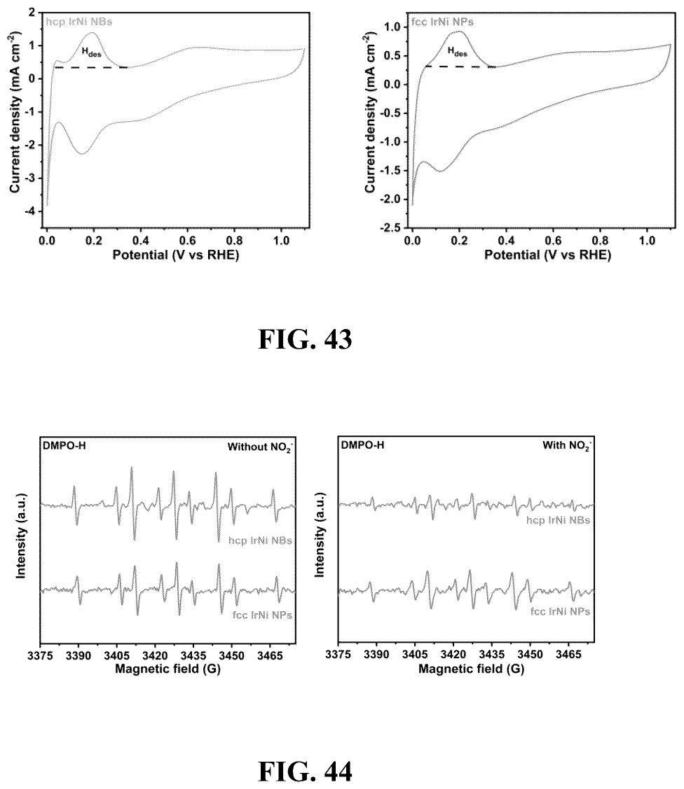

It was found that hcp IrNi NBs demonstrated a much smaller Tafel slope (131 mV dec⁻¹) than that of fcc IrNi NPs (172 mV dec⁻¹), suggesting the efficient electron transfer efficiency and rapid reaction kinetics of hcp IrNi NBs in NO₂RR (FIG. 42). During the electrochemical process of NO₂RR, the subsequent conversion of *NO₂ was significantly influenced by the formation and consumption rate of active hydrogen (H*). As shown in FIG. 43, the corresponding H* area of hcp IrNi NBs was 20.7% larger than that of fcc IrNi NPs, suggesting that the hcp IrNi NBs were capable of providing more H* for the conversion of NO₂⁻ to NH₃.

To directly confirm the existence of H*, EPR test was performed by using 5,5-dimethyl-1-pyrroline N-oxide (DMPO) as the H* trapping reagent. During electrolysis without KNO₂, the hcp IrNi NBs exhibited a much stronger DMPO-H signal compared to fcc IrNi NPs, which suggested that hcp IrNi NBs had a superior ability for the H* generation. Upon the addition of KNO₂, the signal intensity of fcc IrNi NPs only displayed a slight decrease, while a significant reduction of the DMPO-H signal intensity was observed on hcp IrNi NBs (FIG. 44). This result indicated that the H* generated on hcp IrNi NBs could be rapidly consumed, ensuring the swift conversion of nitrogen-containing intermediates into NH₃.

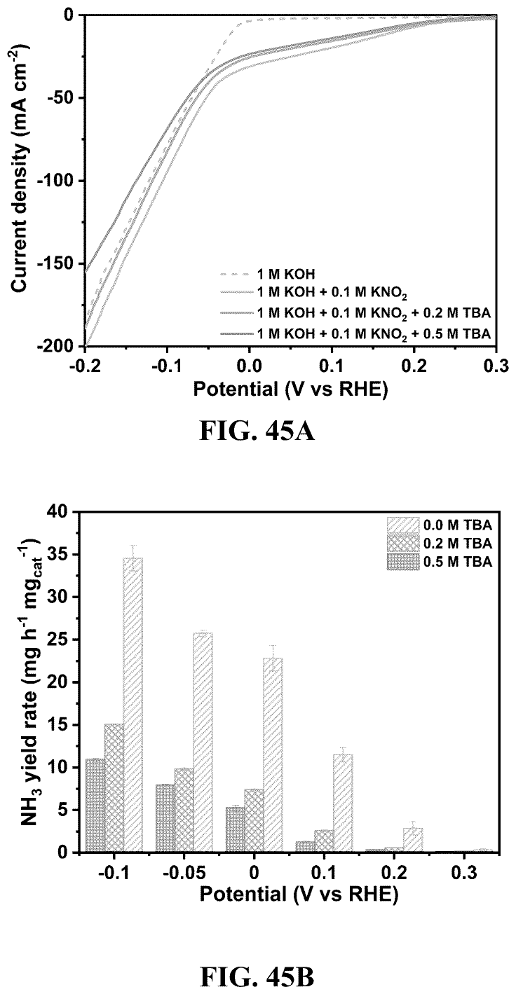

Moreover, a certain amount of tert-butyl alcohol (TBA) was introduced into the electrolyte to effectively trap the generated H*. As the concentration of TBA increases, there was an obvious decrease in both current density and NH₃ yield rate, indicating the critical role of the equilibrium between H* formation and consumption in NH₃ synthesis (FIGS. 45A-45B).

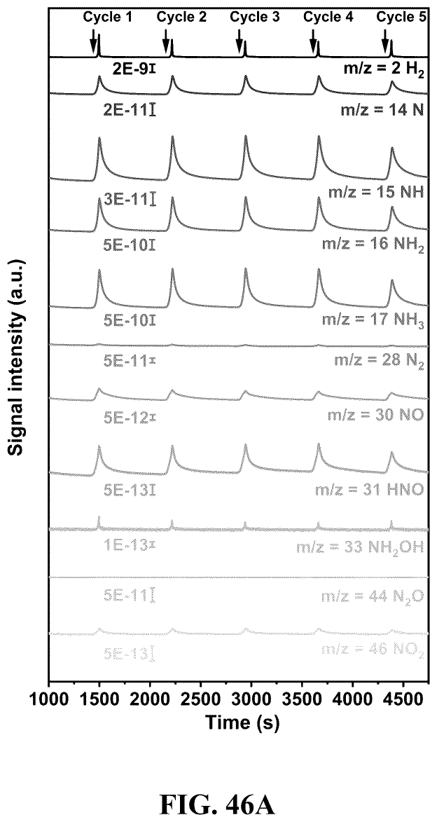

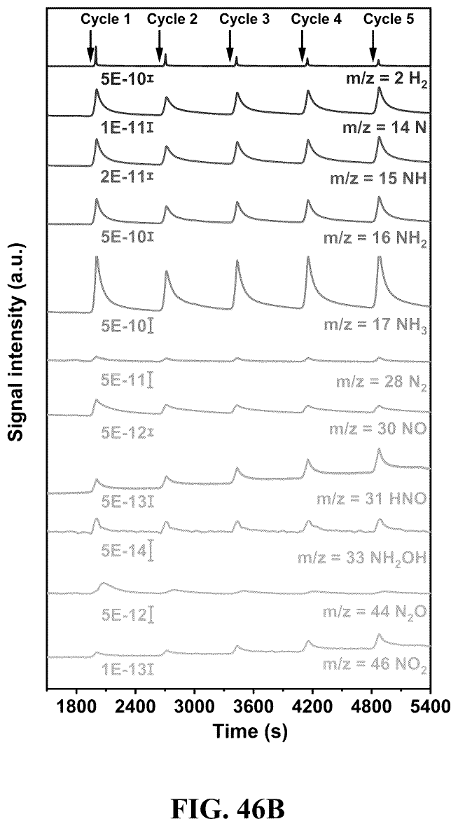

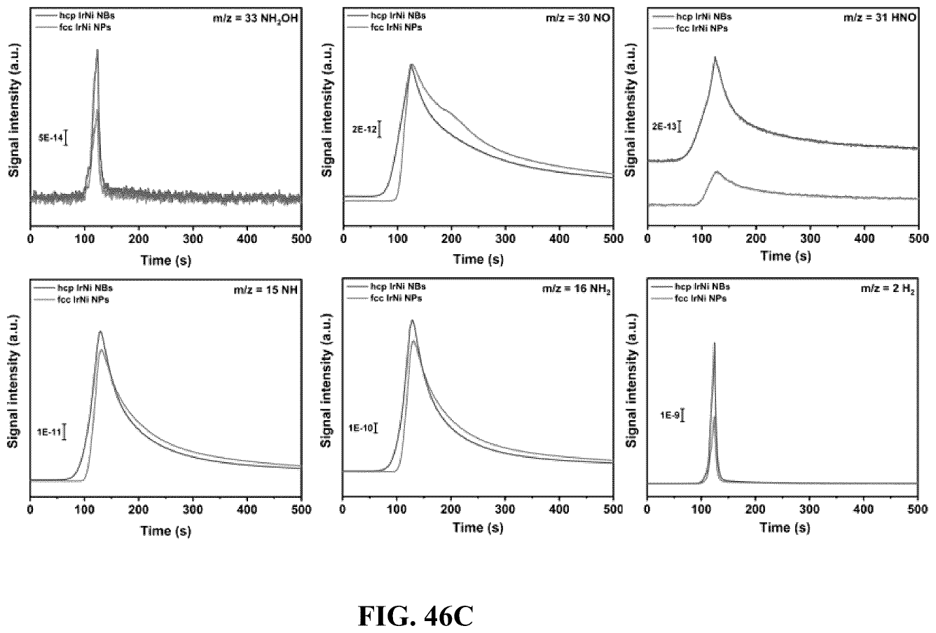

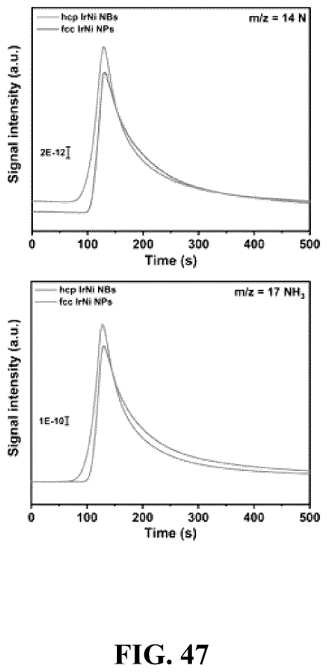

In-situ DEMS characterization was further performed to gain a comprehensive understanding of the reaction process of NO₂RR. Throughout the 5 cycles of linear sweep voltammetry (LSV) scanning, the mass/charge (m/z) signals of 2, 14, 15, 16, 17, 28, 30, 31, 33, and 46 attributed to H₂, N, NH, NH₂, NH₃, N₂, NO, HNO, NH₂OH, and NO₂, respectively, were detected for both hcp IrNi NBs and fcc IrNi NPs (FIGS. 46A-46C). The reaction pathway of NO₂RR was as follow: NO₂*→NO*→NOH* (HNO*)→NHOH* (N*)→NH₂OH* (NH*)→NH₂*→NH₃*→NH₃. Meanwhile, the much higher H₂ peak intensity of hcp IrNi NBs than that of fcc IrNi NPs revealed their stronger ability to generate sufficient H* for the hydrogenation of nitrogen-containing intermediates (FIG. 46C). The hcp IrNi NBs demonstrated a lower overpotential for the formation of several nitrogen-containing intermediates and the ultimate product, i.e., NH₂OH, NO, HNO, N, NH, NH₂, and NH₃ (FIG. 47). These observations uncovered that the hcp IrNi NBs possessed superior catalytic activity for the formation of H* and the subsequent hydrogenation of nitrogen-containing intermediates toward NH₃ production.

### Example 7

### Effect of Solvent and Formaldehyde Solution on Synthesising Hcp IrNi NBs

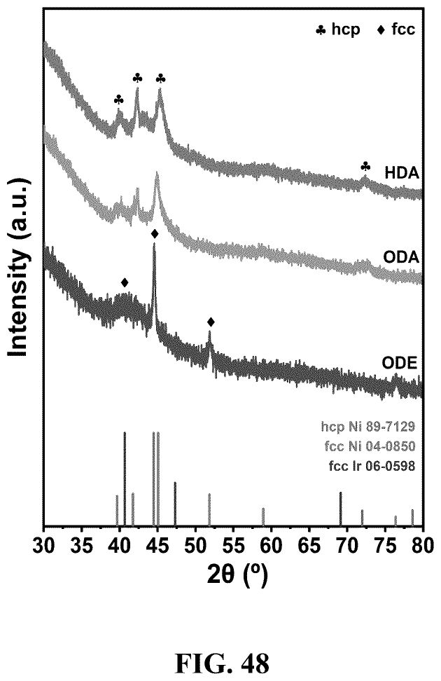

The function of oleylamine (OAm) was investigated by changing OAm to octadecene (ODE), octadecylamine (ODA) and hexadecylamine (HDA). When ODE served as the solvent, IrNi nanodendrites with Ir/Ni atomic ratio of 61.8/38.2 were prepared. No characteristic peaks attributed to hcp phase were found from the XRD pattern (FIG. 48). When ODA and HDA were used to replace OAm, the IrNi nanobranches formed, with the Ir atomic percentages as low as 11.8% and 24.9%, respectively. These results indicated that the formation of hcp phase may be related to the final atomic ratio of Ir/Ni in this reaction system. The amino group in OAm, ODA and HDA coordinated strongly with Ir³⁺, and reduced the reduction tendency of Ir³, resulting in low atomic ratio of Ir/Ni.

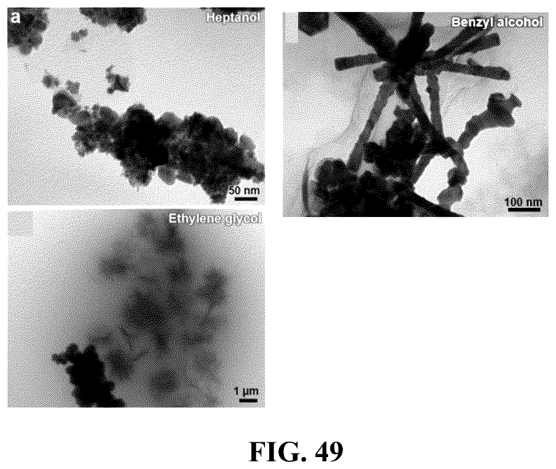

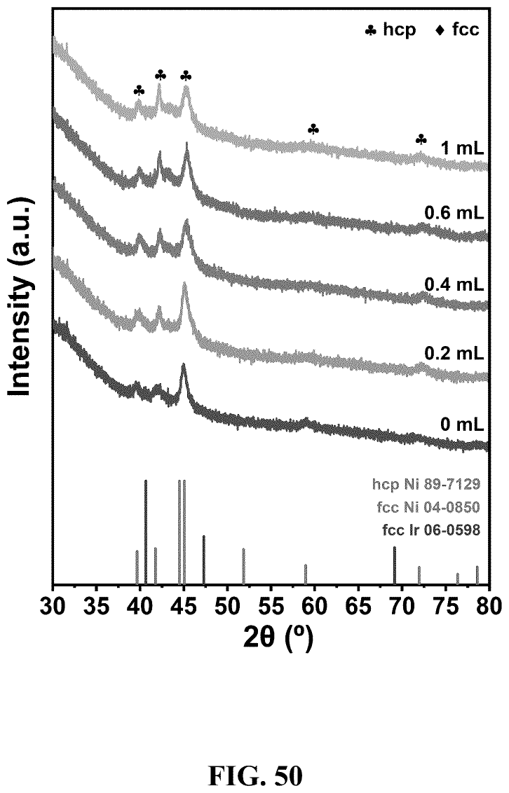

Moreover, the role of oleic acid (OA) was investigated as well. When OA was changed to heptanol and ethylene glycol, only irregular nanoparticles were formed. Though the branched structures were obtained by replacing OA with benzyl alcohol, the uniformity of products was very poor (FIG. 49). Only nanoparticles with hcp phase were obtained without adding OA (FIG. 50). With increasing the amount of OA from 0.2 to 1 mL, the multi-rod-like nanobranches were well maintained with a little change of the Ir/Ni atomic ratio, and their crystal phase was always hcp. These results indicated that OA acted as a structure directing reagent, which was crucial for the formation of branched structures.

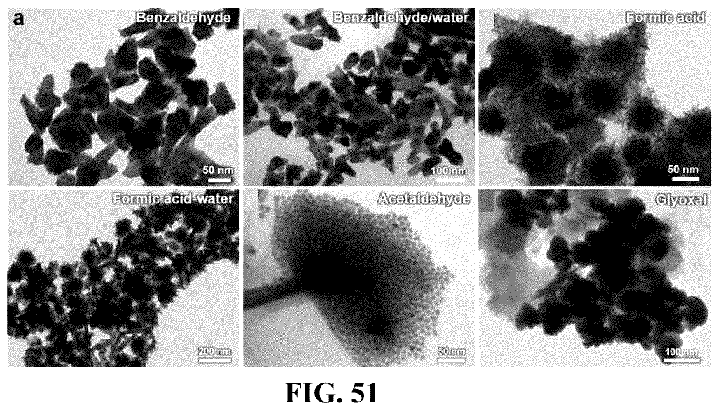

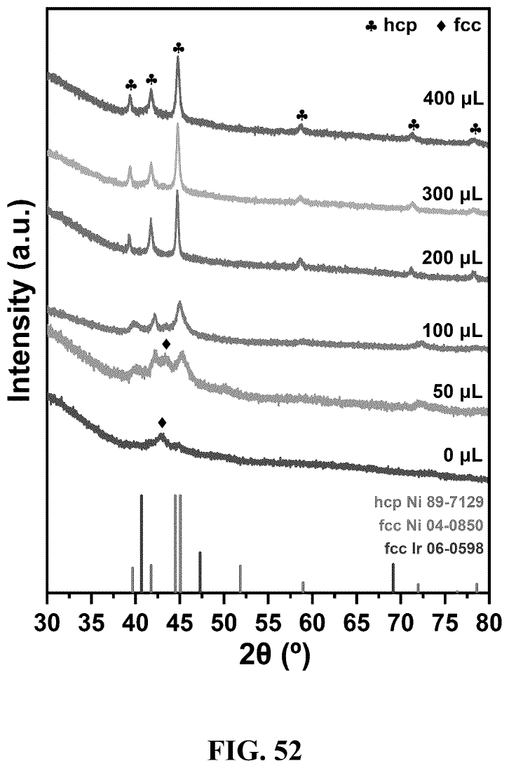

Furthermore, it was found that formaldehyde played a bifunctional role for the formation of well-defined nanobranches and unconventional hcp phase (FIG. 51). In the absence of formaldehyde, the fcc nanoparticles (NPs) were formed. With adding 50 μL of formaldehyde solution, branched nanostructures with the co-existence of fcc and hcp phases were obtained. When 100 μL of formaldehyde solution were added, well-defined IrNi nanobranches with pure hcp phase were successfully synthesized (FIG. 52). Besides, due to H₂ was produced with increasing the dosage of formaldehyde solution, the atomic ratio of Ir decreases from 25.6% to 6.3%, with increasing the amount of formaldehyde solution from 0 to 400 μL. These results suggested that the presence of formaldehyde was significantly essential to the formation of hcp phase, and its dosage would largely affect the morphology of products.

Furthermore, time-dependent experiments were conducted to study the formation mechanism of hcp IrNi NBs. No products were obtained after 1 h reaction. When the reaction time was 2 h, Ni-rich polyhedron-shape nanoparticles as well as some branched structures with Ir/Ni atomic ratio of 15.7/84.3 were formed. As the reaction continued, nanobranches formed at the reaction time of 4 h, which may derive from the polymorphism of Ni. The atomic ratio of Ir/Ni showed a slight decrease to 10.4/89.6. As the reaction proceeded to 6 h, the morphology of samples was similar to that obtained at 4 h. The atomic ratio of Ir/Ni is 14.5/85.5. When the reaction time reached 8 h and 11 h, the morphology of products showed a little change, and the pure hcp phase was still maintained. The Ir/Ni atomic ratios increased from 16.3/83.7 to 20.0/80.0. Finally, after 14 h reaction, the well-defined hcp IrNi NBs with Ir/Ni atomic ratio of 20.5/79.5 was obtained.

Based on the abovementioned control experiments and time-dependent results, a possible mechanism for the synthesis of hcp IrNi NBs had been proposed. Firstly, Ir³⁺ and Ni²⁺ were reduced into Ni-rich fcc IrNi nanoparticles with polyhedron-shape. Then, the Ni-rich IrNi nanobranches gradually grew along the [111]f direction and evolved into pure hcp structure along the [001]ₕ direction due to the syngenetic effects of OAM, OA and formaldehyde. With further increasing the reaction time, the Galvanic replacement reaction between Ni-rich nanobranches and Ir precursor occurred on the surface of Ni-rich IrNi nanobranches. Meanwhile, Ni²⁺ and Ir³⁺ in solution were reduced and selectively deposited along the [001]ₕ direction. At last, the hcp IrNi NBs with a Ni-rich core and Ir-rich shell were successfully obtained.

### Example 8

### Theoretical Calculations

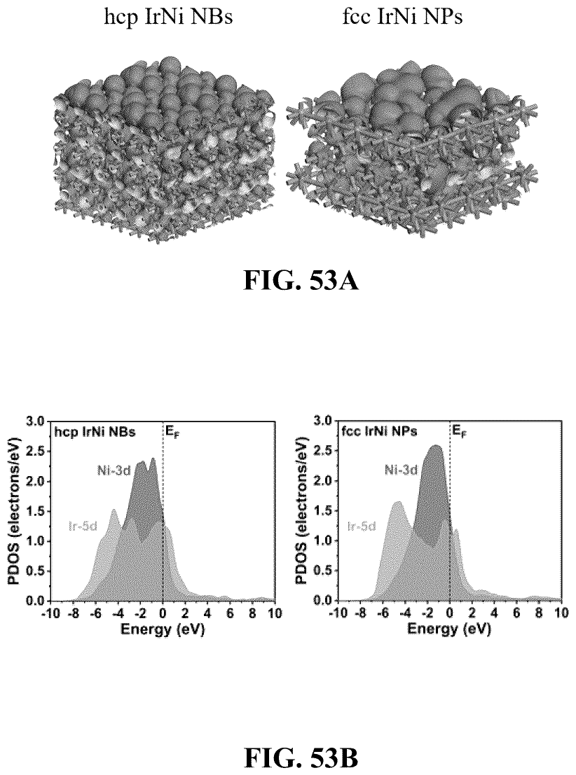

DFT calculations were further performed to investigate the distinct electronic structures and reaction trends for hcp IrNi NBs and fcc IrNi NPs towards the NO₂RR. The surface electronic distributions near the Fermi level (E_{F}) had been demonstrated for comparisons on both hcp and fcc IrNi nanostructures (FIG. 53A). The bonding orbitals showed much stronger contributions on the hcp IrNi surface than the fcc IrNi surface, indicating that the hcp surface is more electroactive. After geometry relaxation, the hcp surface exhibited more evident lattice distortion near the Ir sites, which was potentially attributed to the strong interactions between the Ir-rich shell and the Ni-rich core. Notably, such surface distorted regions had contributed to the bonding orbitals of the surface, leading to significant modulations of surface activity.

Accordingly, the electron transfer efficiency and adsorptions of the key intermediates on the hcp surface were improved to support the fast NO₂RR kinetics. In addition, by comparing different Ir:Ni ratios in the shell structures, the formation energy costs increased as Ir concentration increased. The optimal balance of the electroactivity and stability was obtained by the similar concentrations of Ir and Ni in the shell. The more in-depth analysis of the electronic structures was further performed through the projected partial density of states (PDOSs) on both hcp and fcc IrNi nanostructures (FIG. 53B). For the hcp IrNi NBs, it was noticed that Ni-3d orbitals had dominated the electron density near the E_{F} with slight splitting. Meanwhile, the Ir-5d orbitals shown broad coverage, which pins the Ni-3d orbitals in the middle. This guarantees a stable valence state of Ni on the surface during the electrocatalysis. The e_{g}-t_{2g} splitting in Ir-5d orbitals was nearly absent, revealing the small energy barriers of electron transfer on the surface of hcp IrNi NBs.

In contrast, for the fcc IrNi NPs, the Ni-3d orbitals remained similar while the e_{g}-t_{2g} splitting became more evident with a barrier of 0.98 eV, resulting in reduced electron transfer efficiency. The d-band center of Ir was slightly downshifted from E_{V}-1.80 eV (E_{V}=0 eV) on the hcp IrNi NBs to E_{V}-1.86 eV on the fcc IrNi nanostructures. This revealed a slightly higher valence state of Ir sites in the hcp phase, which were more electroactive to accomplish electron transfer with the intermediates and promote the NO₂RR.

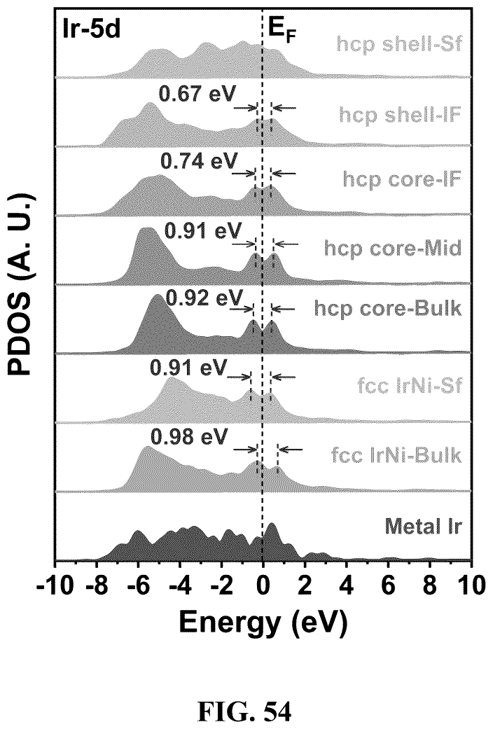

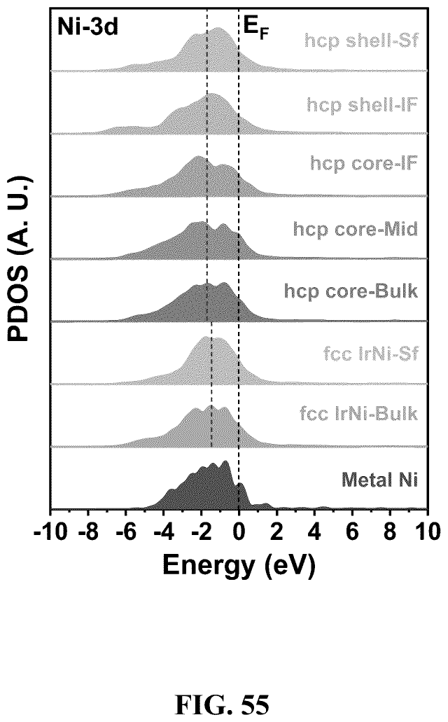

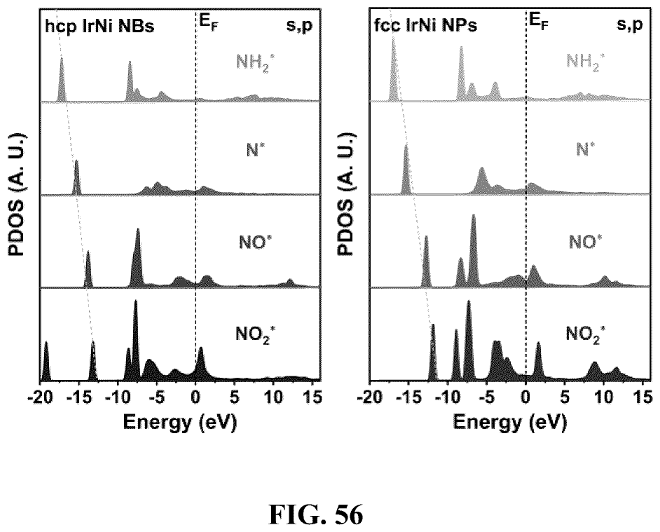

Moreover, the site-dependent PDOSs of Ir in hcp and fcc IrNi were compared to unravel the distinct electronic structures (FIG. 54). For Ir-5d orbitals, the e_{g}-t_{2g} splitting was evident in both bulk Ir metal and the fcc phase of IrNi nanostructures. However, in the hcp IrNi NBs, the e_{g}-t_{2g} splitting was significantly alleviated, especially for the shell part of the core-shell structure. From the core-shell interface to the shell surface, the barrier of the e_{g}-t_{2g} splitting largely decreased with increased electron density near E_{F}, supporting the highly efficient electron transfer behaviors. These were attributed to two strong interactions including the core-shell interaction and the Ir—Ni interaction. For the Ni-3d orbitals, both hcp and fcc phases displayed similar electronic structures to the bulk Ni metal, demonstrating that Ni sites were close to the metallic state (FIG. 55). Compared to the fcc phase and bulk metal, the Ni-3d in the hcp phases were slightly downshifted, which was induced by the stronger interactions between Ni and Ir. The superior electroactivity of the hcp IrNi originated from the stronger electron transfer between Ir and Ni due to the higher alloying level, which optimized the adsorptions of key intermediates to accelerate the NO₂RR. With the optimized electronic structures, the hcp IrNi surface should deliver distinct adsorption behaviors to the fcc IrNi surface, which was distinguished based on the PDOSs evolutions of key intermediates (FIG. 56). From the initial activation of NO₂*, the hcp IrNi showed a good linear relationship to guarantee fast electron transfer for each reaction step. In comparison, it was noticed that the s,p orbitals of adsorbed N* on the fcc IrNi surface exhibited a more evident deviation from the linear relationship, leading to the increased energy barriers during the NO₂RR.

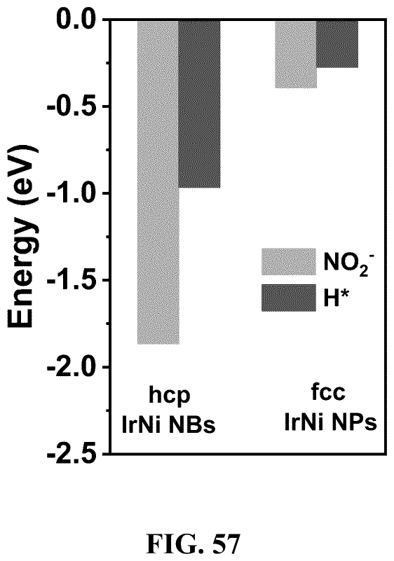

In the meantime, the reaction trends of NO₂RR were explored from the energetic aspects. The adsorption energies of both NO₂⁻ and H* on hcp IrNi NBs were more negative than fcc IrNi NPs, which were critical to quickly activate the NO₂RR process (FIG. 57). Meanwhile, the affinity to NO₂⁻ on hcp IrNi NBs was much stronger than that of the H*, supporting the suppressed HER.

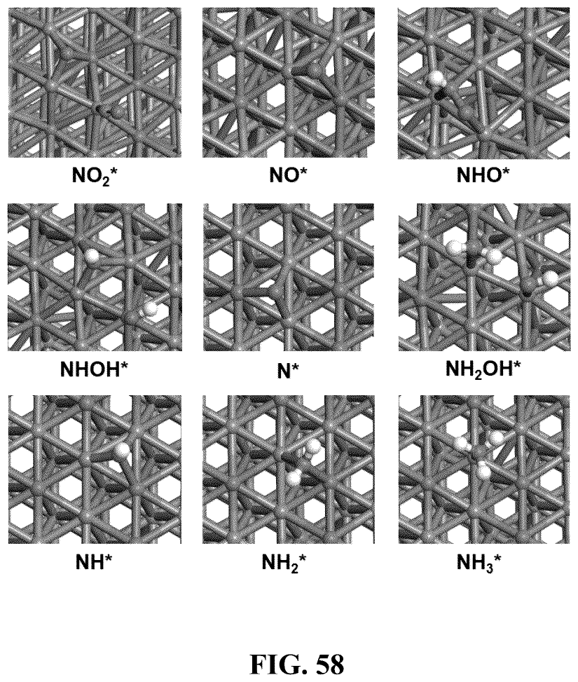

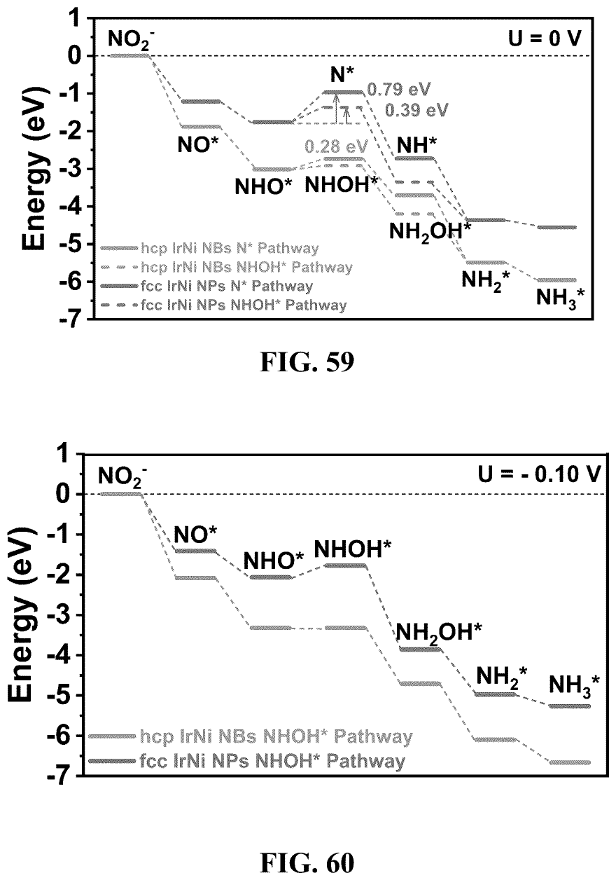

The adsorption configurations were further revealed that NO₂⁻ preferred to stabilize on the hollow active site, which would be dissociated into NO*, supporting the strong electroactivity of the hcp IrNi NBs (FIG. 58). As the reduction processes proceed, the active sites with the most stable adsorption configurations of key intermediates shifted from hollow sites to bridge sites and Ni-top sites at the final reaction steps. The fcc IrNi nanostructures also exhibited a preference for hollow sites. Accordingly, the overall reaction trends of NO₂RR on hcp IrNi NBs were more energetically favored than the fcc IrNi NPs with reduced energy barriers (FIG. 59).

For NO₂RR, the main energy barriers on both hcp and fcc phases occurred at the reduction of HNO*, where the NHOH* pathway showed lower energy barriers than the N* pathway, indicating the formation of N* is the rate-determining step (RDS). The hcp IrNi displayed a much smaller energy barrier (0.28 eV) than that of the fcc IrNi (0.79 eV), resulting in a more efficient NO₂RR process with a higher NH₃ yield rate. The hcp IrNi was able to eliminate all the energy barriers through the NHOH* reaction pathway with an applied potential of −0.10 V, indicating a more efficient NO₂RR than the fcc IrNi under the same potentials (FIG. 60).

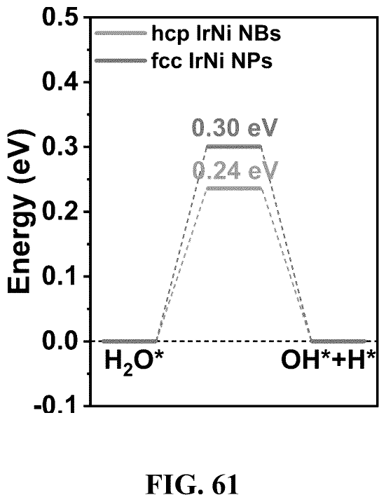

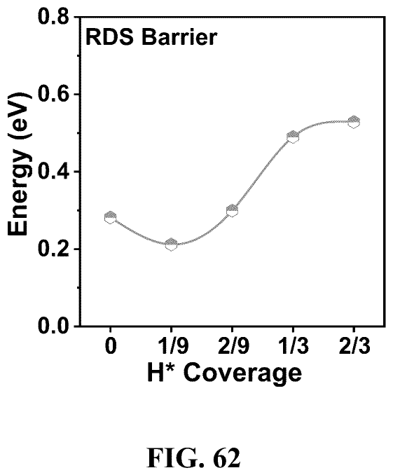

In addition, the influences of the active hydrogen were also unraveled regarding the energy barrier for the water dissociation (FIG. 61). The hcp IrNi NBs required an energy barrier of 0.24 eV to generate active hydrogen, which was easier than the fcc IrNi NPs with a higher energy barrier of 0.30 eV. This confirmed that there are more H* on the hcp IrNi surface to promote the NO₂RR. With the generation of H* on the catalyst surface, the coverage of H* also affected the energy barrier of RDS for NO₂RR (FIG. 62). As the H* coverage increased, the RDS barrier on the hcp IrNi NBs decreased from 0.28 eV to the lowest 0.21 eV at the H* coverage of 1/9. As the H* coverage increased, the RDS barrier was enlarged to 0.48 eV at the ⅓ coverage of H*, which was potentially induced by the block of active sites, suggesting that the suitable H* coverage was beneficial to improve the NO₂RR performance.

Different from the NO₂⁻, H* was preferred to adsorb on the bridge sites of hcp IrNi, which avoided blocking the surface active sites. In contrast to the hcp IrNi, the competition between NO₂⁻ and H* became stronger on the similar preference for active sites, which decreased the NO₂RR performances and enhanced the competitive HER process. Moreover, the HER was potentially affected by the evident increasing energy costs when the H* coverage reached ⅓. With the generation of H* on the catalyst surface, the coverage of H* not only induced stronger surface distortions, but also affected the energy barrier of RDS for NO₂RR (FIG. 62).

In summary, the unconventional hcp IrNi NBs of the present invention are featured with high utilization efficiency of noble metals due to the alloying effect and the construction of unconventional crystal phase structure, which also ensures superior catalytic performance with faster reaction kinetics, higher yield rate, and better long-term durability than other catalysts, indicating outstanding potentials in the related catalytic reactions. The potential market of the present invention could be electrocatalysts and ammonia synthesis through electrochemical method.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

### Definitions

Throughout this specification, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they allow for elements not explicitly recited, but exclude elements that are found in the prior art or that affect a basic or novel characteristic of the present invention.

Furthermore, throughout the specification and claims, unless the context requires otherwise, the word “include” or variations such as “includes” or “including”, will be understood to imply the inclusion of a stated integer or group of integers but not the exclusion of any other integer or group of integers.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

References in the specification to “one embodiment”, “an embodiment”, “an example embodiment”, etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

In the methods of preparation described herein, the steps can be carried out in any order without departing from the principles of the invention, except when a temporal or operational sequence is explicitly recited. Recitation in a claim to the effect that first a step is performed, and then several other steps are subsequently performed, shall be taken to mean that the first step is performed before any of the other steps, but the other steps can be performed in any suitable sequence, unless a sequence is further recited within the other steps. For example, claim elements that recite “Step A, Step B, Step C, Step D, and Step E” shall be construed to mean step A is carried out first, step E is carried out last, and steps B, C, and D can be carried out in any sequence between steps A and E, and that the sequence still falls within the literal scope of the claimed process. A given step or sub-set of steps can also be repeated. Furthermore, specified steps can be carried out concurrently unless explicit claim language recites that they be carried out separately.

“hcp IrNi-based nanostructures” refers to nanostructures composed of an alloy of iridium (Ir) and nickel (Ni) that have a hexagonal close-packed (hcp) crystal structure. “IrNi-based” indicates that the nanostructures are primarily composed of iridium and nickel but may also include other metals.

“Atomic percent” or “at %” refers to the percentage of atoms of each element in a composition relative to the total number of atoms. The atomic percent of each element in the composition should add up to 100%.

“reversible hydrogen electrode (RHE)” is a reference electrode commonly used in electrochemical measurements. The potential of the RHE is set to 0 volts under standard conditions. When electrochemical potentials are reported “vs. RHE,” it means that the measured potential is being compared to the potential of the RHE. This standardization allows for consistent and comparable reporting of electrochemical potentials across different experiments and conditions.

Other definitions for selected terms used herein may be found within the detailed description of the present invention and apply throughout. Unless otherwise defined, all other technical terms used herein have the same meaning as commonly understood to one of ordinary skill in the art to which the present invention belongs.

### REFERENCES: THE DISCLOSURES OF THE FOLLOWING REFERENCES ARE INCORPORATED BY REFERENCE

1. Xu, J., Wang, X., Mao, X., Feng, K., Xu, J., Zhong, J., . . . & Li, Y. (2023). Prominent electronic effect in iridium-alloy-skinned nickel nanoparticles boosts alkaline hydrogen electrocatalysis. Energy & Environmental Science, 16(12), 6120-6126.
2. Lv, F., Zhang, W., Yang, W., Feng, J., Wang, K., Zhou, J., . . . & Guo, S. (2020). Ir-based alloy nanoflowers with optimized hydrogen binding energy as bifunctional electrocatalysts for overall water splitting. Small Methods, 4(6), 1900129.

What is claimed is:

1. An electrocatalyst for efficient nitrite reduction, comprising one or more IrNi-based alloy nanostructures with an unconventional hexagonal close-packed phase, wherein the one or more IrNi-based alloy nanostructures comprise a Ni-rich core and an Ir-rich shell, a feeding atomic ratio of Ni to Ir is between 1:1 to 10:1, and the electrocatalyst exhibits NH₃ Faradaic efficiency of at least 95% at 0 V compared to a reversible hydrogen electrode, a NH₃ yield rate of at least 30 mg h⁻¹ mg_{cat}⁻¹ at −0.1 V compared to the reversible hydrogen electrode, and an energy efficiency of at least 50% at 0 and 0.1 V compared to the reversible hydrogen electrode.

2. The electrocatalyst of claim 1, wherein the feeding atomic ratio consists of 10-30 at % of Ir and 70-90 at % of Ni.

3. The electrocatalyst of claim 1, wherein the one or more IrNi-based alloy nanostructures comprise multi-rod-like nanobranches or nanoparticles.

4. The electrocatalyst of claim 2, wherein the one or more IrNi-based alloy nanostructures comprise IrNi nanobranches, IrRhNi nanobranches, or IrFeNi nanobranches.

5. The electrocatalyst of claim 4, wherein the feeding atomic ratio consists of 10-20 at % of Ir, 70-80 at % of Rh and 1-10 at % of Ni.

6. The electrocatalyst of claim 4, wherein the feeding atomic ratio consists of 10-20 at % of Ir, 70-80 at % of Fe and 10-15 at % of Ni.

7. The electrocatalyst of claim 1, wherein the one or more IrNi-based alloy nanostructures are capable of generating abundant *H for the hydrogenation of nitrogen-containing intermediates and thus reduce the overpotential for NH₃ production.

8. The electrocatalyst of claim 1, wherein each of the one or more IrNi-based alloy nanostructures has an average length of 125.6±4.4 nm and a middle-width of 16.6±0.3 nm.

9. The electrocatalyst of claim 1, wherein the electrocatalyst exhibits the NH₃ Faradaic efficiency of 93.3% at 0 V compared to the reversible hydrogen electrode, even at a low nitrite concentration of 0.01 M.

10. The electrocatalyst of claim 1, wherein the electrocatalyst exhibits a partial current density of NH₃ (j_{NH3}) of at least 40 mA cm⁻² at −0.1 V compared to the reversible hydrogen electrode.

11. The electrocatalyst of claim 1, wherein the one or more IrNi-based alloy nanostructures possess catalytic durability over 20 consecutive electrolysis cycles.

12. A one-pot method for synthesizing an unconventional phase IrNi-based alloy nanostructure, comprising:
co-reducing one or more metal precursors in a solution comprising at least one solvent, and performing ultrasonication to obtain a homogenous solution;
adding a reductant and capping agent to the homogenous solution under vigorous stirring to obtain a growth solution;
heating the growth solution from room temperature to 220° C. and maintained at this temperature for 10-15 hours; and
cooling the growth solution to room temperature and collecting the unconventional phase IrNi-based alloy nanostructure.

13. The one-pot method of claim 12, wherein the one or more metal precursors comprise iridium salts, nickel salts, or a combination thereof.

14. The one-pot method of claim 13, wherein the one or more metal precursors further comprise a noble metal precursor to form the homogenous solution.

15. The one-pot method of claim 14, wherein the noble metal precursor comprises rhodium salts, iron salts, or a combination thereof.

16. The one-pot method of claim 12, wherein the at least one solvent is selected from oleylamine (OAm), oleic acid (OA), or a combination thereof.

17. The one-pot method of claim 12, wherein the reductant and capping agent comprises a formaldehyde solution.

18. The one-pot method of claim 12, wherein concentration of the at least one solvent is in a range of 0.01-0.63 M.

19. The one-pot method of claim 12, wherein concentration of the one or more metal precursors is in a range of 1-10 mg.

20. The one-pot method of claim 12, wherein concentration of the reductant and capping agent is in a range of 0.01-0.8 M.
